(19) United States
(12) Patent Application Publication
(10) Pub. No.: US 2024/0038489 A1
(43) Pub. Date: Feb. 1, 2024

(54) METHOD FOR ATTACHING AN OBJECT TO A MANIPULATOR AND FOR MOVING THE OBJECT IN A PARTICLE BEAM APPARATUS, COMPUTER PROGRAM PRODUCT, AND PARTICLE BEAM APPARATUS

(71) Applicant: Carl Zeiss Microscopy GmbH, Jena (DE)

(72) Inventor: Endre Majorovits, Aalen (DE)

(73) Assignee: Carl Zeiss Microscopy GmbH, Jena (DE)

(21) Appl. No.: 18/360,170

(22) Filed: Jul. 27, 2023

(30) Foreign Application Priority Data
Jul. 28, 2022 (DE) 10 2022 119 041.2

(51) Int. Cl. H01J 37/31; B25J 11/00

(52) U.S. Cl. CPC H01J 37/31; B25J 11/0055

(57) ABSTRACT

The invention relates to a method for fastening an object to a manipulator in a particle beam apparatus and for moving the object in the particle beam apparatus. The invention further relates to a computer program product and a particle beam apparatus, which are provided to carry out the method according to the invention. The method according to the invention includes the following steps: generating a first surface on the manipulator using a particle beam of the particle beam apparatus; generating a second surface on the object using the particle beam, in such a way that the second surface corresponds to the first surface; arranging the first surface at the second surface such that the manipulator is arranged at the object; fastening the object to the manipulator in a boundary region between the first surface and the second surface using the particle beam; and moving the object fastened to the manipulator using the manipulator and/or a mobile object stage, on which the object is arranged.

### CROSS-REFERENCE TO RELATED APPLICATIONS

This application claims the priority of the German patent application No. 10 2022 119 041.2, filed on Jul. 28, 2022, which is incorporated herein by reference.

### TECHNICAL FIELD

This application relates to fastening an object to a manipulator in a particle beam apparatus and moving the object in the particle beam apparatus.

### BACKGROUND

The practice of examining and/or analyzing objects by light microscopy has been known for a long time. In light microscopy, use is made of a light microscope which includes a beam generator for generating a light beam, an objective lens for focusing the light beam onto the object and a display device for displaying an image and/or an analysis of the object. By way of example, the display device is embodied as an eyepiece.

Further, the practice of examining objects with electron beam apparatuses has been known for a long time. By way of example, electron beam apparatuses, in particular a scanning electron microscope (also referred to as SEM below) and/or a transmission electron microscope (also referred to as TEM below), are used to examine objects (samples) in order to obtain knowledge with respect to the properties and the behavior under certain conditions.

In an SEM, an electron beam (also referred to as primary electron beam below) is generated using a beam generator and focused onto an object to be examined by way of a beam guiding system. The primary electron beam is guided in a scanning manner over a surface of the object to be examined using a deflection device in the form of a scanning device. Here, the electrons of the primary electron beam interact with the object to be examined. As a consequence of the interaction, in particular, electrons are emitted by the object (so-called secondary electrons) and electrons of the primary electron beam are backscattered (so-called backscattered electrons). The secondary electrons and backscattered electrons are detected and used for image generation. An image representation of the object to be examined is thus obtained.

In the case of a TEM, a primary electron beam is likewise generated using a beam generator and guided onto an object to be examined using a beam guiding system. The primary electron beam passes through the object to be examined. When the primary electron beam passes through the object to be examined, the electrons of the primary electron beam interact with the material of the object to be examined. The electrons passing through the object to be examined are imaged onto a luminescent screen or onto a detector (for example a camera) by a system that includes an objective and a projection unit. Here, imaging can also take place in the scanning mode of a TEM. Usually, such a TEM is referred to as STEM. Additionally, provision can be made for detecting electrons backscattered at the object to be examined and/or secondary electrons emitted by the object to be examined using a further detector in order to image an object to be examined.

Furthermore, it is known from the prior art to use combination apparatuses for examining objects, where both electrons and ions can be guided onto an object to be examined. By way of example, it is known to additionally equip an SEM with an ion beam column. An ion beam generator arranged in the ion beam column is used to generate ions that are used for preparing an object (for example ablating material of the object or applying material to the object) or else for imaging. For this purpose, the ions are scanned over the object using a deflection device in the form of a scanning device. The SEM serves in particular for observing the preparation, but also for further examination of the prepared or unprepared object.

The practice of arranging an object to be examined with a particle beam apparatus on an object holder, which in turn is arranged on an object stage, is known. The object stage is arranged in a sample chamber of the particle beam apparatus. The object stage is mobile, the mobile embodiment of the object stage being ensured by a plurality of movement units, from which the object stage is assembled. The movement units enable a movement of the object stage in at least one specified direction. Object stages that have a plurality of translational movement units (e.g., approximately 3 to 4 translational movement units) and a plurality of rotational movement units (e.g., 2 to 3 rotational movement units), in particular, are known. By way of example, an object stage which is movably arranged along a first translation axis (for example, an x-axis), along a second translation axis (for example, a y-axis), and along a third translation axis (for example, a z-axis) is known. The first translation axis, the second translation axis and the third translation axis are oriented perpendicular to one another. Further, the known object stage is embodied to be rotatable about a first rotation axis and about a second rotation axis, which is aligned perpendicular to the first rotation axis.

The prior art has disclosed gas feed devices which include one precursor reservoir or a plurality of precursor reservoirs, where at least one precursor is stored in a respective precursor reservoir. A precursor selected for a certain process—e.g., ablating material of the object or applying material to the object—is let out through an outlet of the precursor reservoir and guided to the object.

By way of example, the precursor is stored as a solid or liquid substance in a known precursor reservoir. In order to bring the precursor into the gaseous phase, the precursor is evaporated (transition from the liquid phase into the gaseous phase) or sublimated (direct transition from the solid phase into the gaseous phase) within the precursor reservoir. Subsequently, the precursor in the gaseous phase is guided via at least one needle-shaped capillary to the object, for example, such that the precursor can interact with the particle beam.

The prior art teaches the practice of fastening an object, which is prepared from an object material, to a manipulator by depositing a material. The object is connected to the manipulator in the process. For this purpose, the methods explained hereinbelow are known from the prior art.

At a connection point between the object on the one hand and the manipulator on the other hand, material is deposited in such a way as a result of feeding a precursor and a particle beam that the object is securely connected to the manipulator. If the object is connected to the manipulator in this way, then the object can be taken from the object material using the manipulator once the object has been separated from the object material, for example by using a particle beam.

As an alternative to fastening the object to the manipulator by depositing a material, the practice of using a micro-gripper with a first clamping unit and with a second clamping unit as a manipulator is known. The object is held in clamped fashion between the first clamping unit and the second clamping unit and lifted out of the object material using the micro-gripper. However, the object may be undesirably influenced, and the object may even be destroyed, as a result of the force exerted on the object.

The prior art also teaches the examination of a frozen object using a light microscope and/or a particle beam apparatus. By way of example, this is advantageous when examining biological objects. To this end, the frozen object is for example prepared out of a frozen object material and arranged on a coolable object holder. By way of example, the object holder is able to be cooled to a temperature of −140° C. or less than −140° C. using liquid nitrogen or liquid helium. Hereinabove and also hereinbelow, temperatures below −50° C. are referred to as cryo-temperatures. The aforementioned object holder is arranged on an object stage of a light microscope or a particle beam apparatus.

To arrange a frozen object on the object holder, it is known to initially arrange the frozen object on a manipulator and use the manipulator to move the frozen object to the object holder on which the frozen object is ultimately arranged. Usually, the manipulator is cooled in order to maintain the desired temperature. To fasten the frozen object to the cooled manipulator, a precursor is guided firstly to the frozen object and secondly to the cooled manipulator via a gas feed device. On account of the low temperature, the precursor is deposited on the frozen object and on the manipulator, especially in the boundary region between the frozen object and the manipulator, and connects the frozen object to the manipulator in this way. Accordingly, the frozen object is arranged on the manipulator. The above-described, known method is frequently also referred to as cold deposition. However, a disadvantage of this method is that the precursor is arranged not only in the boundary region between the frozen object and the manipulator but on all cold surfaces in principle, in particular on the object, the object material from which the frozen object is taken, and the manipulator itself. In this respect, numerous surfaces are contaminated. The contaminations make further examinations of objects of the object material more difficult, or even render such further examinations impossible. In particular, the manipulator is contaminated to such an extent that the manipulator has to be either cleaned or even fully replaced prior to reuse.

The prior art also teaches a further method for arranging an object at a manipulator. In this case, material is ablated from the manipulator using a particle beam and applied in the boundary region between the object and the manipulator such that the object is fastened to the manipulator.

With regard to the prior art, reference is made to US 2013/0001191 A1, WO 2012/138738 A2, US 2021/0225610 A1 and DE 10 2020 112 220 A1.

### SUMMARY OF THE INVENTION

The system described herein is based on a method and a particle beam apparatus for carrying out the method, to provide a good connection, in particular, of frozen objects to a manipulator, so that no bothersome contaminations of components arise.

The system described herein serves to fasten an object to a manipulator in a particle beam apparatus and move the object in the particle beam apparatus. By way of example, the particle beam apparatus is configured to analyze, observe, and/or process the object. In particular, the particle beam apparatus includes at least one beam generator for generating a particle beam with charged particles. The charged particles are electrons or ions, for example. By way of example, the particle beam apparatus includes at least one objective lens for focusing the particle beam onto the object and/or onto a manipulator, to which the object can be fastened. Further, the particle beam apparatus includes in particular at least one detector for detecting interaction particles and/or interaction radiation, arising from an interaction of the particle beam with the object upon incidence of the particle beam on the object and/or arising from an interaction of the particle beam with the manipulator upon incidence of the particle beam on the manipulator.

By way of example, the manipulator is in the form of a micro-manipulator. In particular, provision is made for the manipulator to include an end region on which an object is arrangeable. Further, provision is made for the manipulator to be mobile. To this end, provision is made in particular for the manipulator to be connected to a movement device, so that the manipulator is movable. By way of example, the movement device enables a movement of the manipulator in at least one specific direction. In particular, the movement device may have a plurality of translational movement units (e.g., 3 to 4 translational movement units) and a plurality of rotational movement units (e.g., 2 to 3 rotational movement units). By way of example, the manipulator is configured so that the manipulator is movable along a first translation axis (for example, an x-axis), along a second translation axis (for example, a y-axis), and along a third translation axis (for example, a z-axis). By way of example, the first translation axis, the second translation axis, and the third translation axis are oriented perpendicular to one another. Further, the manipulator is configured to be rotatable about a first rotation axis and about a second rotation axis, which is aligned perpendicular to the first rotation axis.

In the method according to the system described herein, provision is made for at least one first surface to be generated on the manipulator using a particle beam of the particle beam apparatus, with the particle beam including charged particles. As mentioned hereinabove, the charged particles are for example electrons or ions. In particular, provision is made for the particle beam with the charged particles to be guided onto the manipulator and over the manipulator. By way of example, the particle beam is scanned over the surface of the manipulator using a scanning device of the particle beam apparatus. In particular, provision is made for the first surface to be generated by ablating material from the manipulator and/or by applying material to the manipulator. By way of example, a gas feed device that includes one precursor reservoir or a plurality of precursor reservoirs, with at least one precursor being stored in a respective precursor reservoir, is used to this end to let out a precursor from an outlet of the precursor reservoir and guide the precursor to the manipulator. As a result of the interaction of the precursor with the particle beam, the first surface is generated by ablating material from the manipulator and/or by applying material to the manipulator.

In the method according to the system described herein, provision is made further for at least one second surface to be generated on the object using the particle beam of the particle beam apparatus. In particular, provision is made for the particle beam with the charged particles to be guided onto the object and over the object. By way of example, the particle beam is scanned over the surface of the object using the scanning device of the particle beam apparatus. In particular, provision is made for the second surface to be generated by ablating material from the object and/or by applying material to the object. By way of example, the gas feed device is used to this end to let a precursor out of the outlet of the precursor reservoir and guide the precursor to the object. As a result of the interaction of the precursor with the particle beam, the second surface is generated by ablating material from the object and/or by applying material to the object.

In the method according to the system described herein, provision is made for the first surface and the second surface to be generated in such a way that the second surface corresponds to the first surface. Expressed in other words, there is a correspondence between the second surface and the first surface. Expressed in yet more words, the first surface and the second surface are configured so that the first surface and the second surface correspond to one another. By way of example, the correspondence between the first surface and the second surface is up to 50%, up to 60%, up to 70%, up to 80%, up to 90% or up to 100%.

The method according to the system described herein also provides for the first surface to be arranged at the second surface such that the manipulator is arranged at the object. In particular, the first surface is arranged at the second surface by moving the manipulator and/or by moving the object. By way of example, the movement of the manipulator is made available by the aforementioned movement device. In particular, the object is moved by a mobile object stage, on which the object is arranged. By way of example, the object stage is arranged in a sample chamber of the particle beam apparatus. The mobility of the object stage is ensured in particular by a plurality of movement units, from which the object stage is assembled. The movement units enable a movement of the object stage in at least one specified direction. In particular, a plurality of translational movement units (e.g., 3 to 4 translational movement units) and a plurality of rotational movement units (e.g., 2 to 3 rotational movement units) are provided. By way of example, the object stage is configured such that the object stage is mobile along a first translation axis (for example, an x-axis), along a second translation axis (for example, a y-axis), and along a third translation axis (for example, a z-axis). By way of example, the first translation axis, the second translation axis, and the third translation axis are oriented perpendicular to one another. Further, the object stage is configured in particular to be rotatable about a first rotation axis and about a second rotation axis, which is aligned perpendicular to the first rotation axis.

In the method according to the system described herein, provision is further made for the object to be fastened to the manipulator in a boundary region between the first surface and the second surface using the particle beam of the particle beam apparatus. By way of example, provision is made for the particle beam with the charged particles to be guided onto the object and over the object. In particular, the particle beam is scanned over the surface of the object using the scanning device of the particle beam apparatus. In the process, material of the object is ablated and reapplied in the boundary region between the first surface and the second surface, with the result that the object is fastened to the manipulator. In addition or as an alternative thereto, provision is made for the particle beam with the charged particles to be guided onto the manipulator and over the manipulator. By way of example, the particle beam is scanned over the surface of the manipulator using the scanning device of the particle beam apparatus. In the process, material of the manipulator is ablated and reapplied in the boundary region between the first surface and the second surface, with the result that the object is fastened to the manipulator.

In the method according to the system described herein, provision is further made for the object fastened to the manipulator to be moved using the manipulator and/or the mobile object stage, on which the object is arranged.

The generation of the first surface and the second surface, which corresponds to the first surface, and the arrangement of the first surface on the second surface allow a particularly good connection and a particularly good hold of the object on the manipulator in the boundary region between the first surface and the second surface. It was found that the method according to the system described herein is particularly well suited to the arrangement of frozen objects on a manipulator, in particular on a cooled manipulator. Accordingly, a contamination of components, which might occur within the scope of a cold deposition as explained above, is avoided. As a result, the manipulator can be used multiple times without the manipulator having to be cleaned or even replaced.

In an embodiment of the method according to the system described herein, provision is additionally or alternatively made for the first surface to be generated with a first shape and for the second surface to be generated with a second shape. Expressed in other words, the first surface is generated in such a way that the first surface has the first shape. Further, the second surface is generated in such a way that the second surface has the second shape. Following the arrangement of the first surface on the second surface, the first shape rests against the second shape. In addition or as an alternative thereto, provision is made for the first shape to engage in the second shape and/or for the second shape to engage in the first shape. In particular, provision is made for the first surface to be generated as a plane surface and/or for the second surface to be generated as a plane surface. By way of example, the first surface and the second surface are generated in such a way that the first surface and the second surface are alignable parallel to one another. Expressed in other words, the first surface and the second surface are generated so that the first surface extends parallel to the second surface after being arranged at the second surface.

The invention is not restricted to the above-described embodiments of the first surface and the second surface. Rather, the first surface and/or the second surface can have any shape that is suitable for the invention. By way of example, the first surface and/or the second surface can be both rounded-off and have plane areas. All that is essential is that the first surface corresponds to the second surface.

In a further embodiment of the method according to the system described herein, provision is additionally or alternatively made for a plurality of first surfaces and a plurality of second surfaces to be generated. Thus, in this further embodiment of the method according to the system described herein, provision is made for at least one further first surface to be generated on the manipulator using the particle beam of the particle beam apparatus. In particular, in this case, provision is also made for the particle beam with the charged particles to be guided onto the manipulator and over the manipulator. By way of example, the particle beam is scanned over the surface of the manipulator using the scanning device of the particle beam apparatus. In particular, provision is made for the further first surface to be generated by ablating material from the manipulator and/or by applying material to the manipulator. By way of example, the gas feed device is used to this end to let a precursor out of an outlet of the precursor reservoir and guide the precursor to the manipulator. As a result of the interaction of the precursor with the particle beam, the further first surface is generated by ablating material from the manipulator and/or by applying material to the manipulator. Further, provision is made for at least one further second surface to be generated on the object using the particle beam of the particle beam apparatus. In particular, provision is made for the particle beam with the charged particles to be guided onto the object and over the object. By way of example, the particle beam is scanned over the surface of the object using the scanning device of the particle beam apparatus. In particular, provision is made for the further second surface to be generated by ablating material from the object and/or by applying material to the object. By way of example, the gas feed device is used to this end to let a precursor out of the outlet of the precursor reservoir and guide the precursor to the object. As a result of the interaction of the precursor with the particle beam, the further second surface is generated by ablating material from the object and/or by applying material to the object. The further first surface and the further second surface are generated in such a way that the further second surface corresponds to the further first surface. Expressed in other words, there is a correspondence between the further second surface and the further first surface. Expressed in yet more words, the further first surface and the further second surface are configured so that the further first surface and the further second surface correspond to one another. By way of example, the correspondence between the further first surface and the further second surface is up to 50%, up to 60%, up to 70%, up to 80%, up to 90%, or up to 100%.

In this embodiment according to the system described herein, provision is further made for the further first surface to be arranged at the further second surface such that the manipulator is arranged at the object. In particular, the further first surface is arranged at the further second surface by moving the manipulator and/or by moving the object. By way of example, the movement of the manipulator is made available by the aforementioned movement device. In particular, the object is moved by the mobile object stage, on which the object is arranged.

Moreover, this embodiment according to the system described herein provides for the object to be fastened to the manipulator in a boundary region between the further first surface and the further second surface using the particle beam of the particle beam apparatus. By way of example, provision is made for the particle beam with the charged particles to be guided onto the object and over the object. In particular, the particle beam is scanned over the surface of the object using the scanning device of the particle beam apparatus. In the process, material of the object is ablated and reapplied in the boundary region between the further first surface and the further second surface, with the result that the object is fastened to the manipulator. In addition or as an alternative thereto, provision is made for the particle beam with the charged particles to be guided onto the manipulator and over the manipulator. By way of example, the particle beam is scanned over the surface of the manipulator using the scanning device of the particle beam apparatus. In the process, material of the manipulator is ablated and reapplied in the boundary region between the further first surface and the further second surface, with the result that the object is fastened to the manipulator.

In an embodiment of the method according to the system described herein, provision is additionally or alternatively made for the further first surface to be generated with a first shape and for the further second surface to be generated with a second shape. Expressed in other words, the further first surface is generated in such a way that the further first surface has the first shape. Further, the further second surface is generated in such a way that the further second surface has the second shape. Following the arrangement of the further first surface on the further second surface, the first shape of the further first surface rests against the second shape of the further second surface. In addition or as an alternative thereto, provision is made for the first shape of the further first surface to engage in the second shape of the further second surface and/or for the second shape of the further second surface to engage in the first shape of the further first surface. In particular, provision is made for the further first surface to be generated as a plane surface and/or for the further second surface to be generated as a plane surface. By way of example, the further first surface and the further second surface are generated in such a way that the further first surface and the further second surface are alignable parallel to one another. Expressed in other words, the further first surface and the further second surface are generated so that the further first surface extends parallel to the further second surface after being arranged at the further second surface.

The invention is not restricted to the above-described embodiments of the further first surface and the further second surface. Rather, the further first surface and/or the further second surface can have any shape that is suitable for the invention. By way of example, the further first surface and/or the further second surface can be both rounded-off and have plane areas. All that is essential is that the further first surface corresponds to the further second surface.

Embodiments of the first surface generated on the manipulator and/or of the second surface generated on the object are described hereinbelow. Corresponding statements also apply to the further first surface and/or the further second surface.

Thus, in an embodiment of the method according to the system described herein, provision is additionally or alternatively made for the particle beam of the particle beam apparatus to be used to generate a structure unit on the first surface before the object is fastened to the manipulator. When fastening the object to the manipulator, the structure unit generated on the first surface is arranged at the second surface. The structure unit may have any embodiment, as will still be explained in detail hereinbelow.

In a further embodiment of the method according to the system described herein, provision is additionally or alternatively made for the particle beam of the particle beam apparatus to be used to generate a structure unit, having at least one projection, on the first surface before the object is fastened to the manipulator. When fastening the object to the manipulator, the projection is arranged at the second surface.

In yet a further embodiment of the method according to the system described herein, provision is additionally or alternatively made for the particle beam of the particle beam apparatus to be used to generate a first structure unit on the first surface before the object is fastened to the manipulator. When fastening the object to the manipulator, the first structure unit generated on the first surface is arranged at a second structure unit of the second surface of the object. The first structure unit and the second structure unit may have any embodiment, as will still be explained in detail hereinbelow.

In yet an even further embodiment of the method according to the system described herein, provision is additionally or alternatively made for the particle beam of the particle beam apparatus to be used to generate a first structure unit, having at least one first projection, on the first surface before the object is fastened to the manipulator. When fastening the object to the manipulator, the first projection of the first structure unit is arranged in a first cutout in a second structure unit of the second surface of the object.

In an embodiment of the method according to the system described herein, provision is additionally or alternatively made, firstly, for the particle beam of the particle beam apparatus to be used to generate a first structure unit on the first surface before the object is fastened to the manipulator. Secondly, the particle beam of the particle beam apparatus is used to generate a second structure unit on the second surface. When fastening the object to the manipulator, the first structure unit generated on the first surface is arranged at the second structure unit, which was generated on the second surface.

In a further embodiment of the method according to the system described herein, provision is additionally or alternatively made, firstly, for the particle beam of the particle beam apparatus to be used to generate a first structure unit, having at least one first projection, on the first surface before the object is fastened to the manipulator. Secondly, the particle beam of the particle beam apparatus is used to generate a second structure unit, which has at least one first cutout, on the second surface. When fastening the object to the manipulator, the first projection is arranged in the first cutout.

As mentioned above, the aforementioned structure units may have any embodiment. By way of example, the aforementioned structure units have at least one aforementioned projection. In particular, provision is made for at least one of the aforementioned structure units to have a comb-like embodiment. Such a structure unit includes a plurality of tines (for example in the form of projections) and cutouts respectively arranged between two tines.

As mentioned above, to fasten the object to the manipulator in yet an even further embodiment of the method according to the system described herein, provision is additionally or alternatively made for the particle beam of the particle beam apparatus to be guided to the object in such a way that material of the object is applied in the boundary region between the first surface and the second surface. To fasten the object to the manipulator, provision is additionally or alternatively made for the particle beam of the particle beam apparatus to be guided to the manipulator in such a way that material of the manipulator is applied in the boundary region between the first surface and the second surface. Reference is made to the explanations given hereinbefore, which also apply here.

In yet a further embodiment of the method according to the system described herein, provision is additionally or alternatively made for the object to be removed from an object material when the object is moved using the manipulator and/or the object stage. The object material is the material out of which the object intended to be analyzed, processed, and/or imaged was prepared.

In an embodiment of the method according to the system described herein, provision is additionally or alternatively made for the object to be cut out of an object material using the particle beam of the particle beam apparatus before the object is moved.

In a further embodiment of the method according to the system described herein, provision is additionally or alternatively made for the object to be fastened to an object holder using the particle beam of the particle beam apparatus after the object has been moved using the manipulator and/or the object stage. By way of example, the object holder is in the form of a TEM object holder. However, the invention is not restricted to such object holders. Rather, any suitable object holder may be used.

By way of example, to fasten the object to the object holder, provision is made for the particle beam with the charged particles to be guided onto the object and over the object. By way of example, the particle beam is scanned over the surface of the object using the scanning device of the particle beam apparatus. In the process, material of the object is ablated and reapplied in the boundary region between the object and the object holder, with the result that the object is fastened to the object holder. In addition or as an alternative thereto, provision is made for the particle beam with the charged particles to be guided onto the object holder and over the object holder. By way of example, the particle beam is scanned over the surface of the object holder using the scanning device of the particle beam apparatus. In the process, material of the object holder is ablated and reapplied in the boundary region between the object and the object holder, with the result that the object is fastened to the object holder.

In an even further embodiment of the method according to the system described herein, provision is additionally or alternatively made for the object to be released from the manipulator using the particle beam of the particle beam apparatus after the object has been moved using the manipulator and/or the object stage. By way of example, this is implemented after the object has been fastened to the aforementioned object holder. By way of example, to release the object from the manipulator, provision is made for the particle beam with the charged particles to be guided onto the object and over the object. By way of example, the particle beam is scanned over the surface of the object using the scanning device of the particle beam apparatus. In the process, material is ablated in the boundary region between the object and the manipulator such that the object is released from the manipulator.

In yet a further embodiment of the method according to the system described herein, provision is additionally or alternatively made for the object to be fastened to the manipulator using a gas which is provided by a gas feed device. Reference is made to the explanations given hereinbefore, which also apply here.

In yet a further embodiment of the method according to the system described herein, provision is additionally or alternatively made for the manipulator and/or the object to be cooled. To this end, the manipulator is arranged on a first heating and/or cooling device, for example. By way of example, the object is arranged on a second heating and/or cooling device. In particular, the manipulator and/or the object is/are cooled to a temperature of −140° C. or less than −140° C. using liquid nitrogen or using liquid helium. Hereinabove and also hereinbelow, temperatures below −50° C. are referred to as cryo-temperatures.

In yet a further embodiment of the method according to the system described herein, provision is additionally or alternatively made for an object which is embodied to be thicker at the first surface than in other regions of the object to be used as the object. By way of example, this ensures that sufficient material is made available for redeposition (that is to say an application of material using the particle beam after material has been ablated using the particle beam).

The system described herein also relates to a computer program product having a program code, which can be loaded or is loaded into a processor and which, when executed, controls a particle beam apparatus in such a way that the method according to the system described herein having one of the features specified herein or having a combination of at least two of the features specified herein is carried out.

The system described herein further relates to a particle beam apparatus for analyzing, imaging and/or processing an object. The particle beam apparatus according to the system described herein is configured to carry out a method having at least one of the features specified herein or having a combination of at least two of the features specified herein.

The particle beam apparatus according to the system described herein includes at least one beam generator for generating a particle beam with charged particles. The charged particles are electrons or ions, for example. The particle beam apparatus includes at least one mobile manipulator for arranging and moving the object, and at least one mobile object stage. The object is arrangeable on the object stage. With regard to the object stage and the mobile manipulator, reference is made to the explanations given further above, which also apply here. Moreover, the particle beam apparatus according to the system described herein is provided with at least one objective lens for focusing the particle beam onto the object and/or onto the manipulator. Further, the particle beam apparatus according to the system described herein includes at least one scanning device for scanning the particle beam over the object and/or over the manipulator. Additionally, the particle beam apparatus includes at least one detector unit for detecting interaction particles and/or interaction radiation, arising from an interaction of the particle beam with the object upon incidence of the particle beam on the object and also arising from an interaction of the particle beam with the manipulator upon incidence of the particle beam on the manipulator. The particle beam apparatus according to the system described herein includes a processor in which a computer program product having at least one of the features specified herein or having a combination of at least two of the features specified herein is loaded.

In an embodiment of the particle beam apparatus according to the system described herein, provision is made, additionally or alternatively, for the particle beam apparatus to include a gas feed device for feeding a gas. With regard to the embodiment of the gas feed device, reference is made to the explanations further hereinabove, which also apply here.

In a further embodiment of the particle beam apparatus according to the system described herein, provision is made, additionally or alternatively, for the particle beam apparatus to include at least one heating and/or cooling device for setting a temperature of the manipulator and/or the object. By way of example, the particle beam apparatus according to the system described herein includes a first heating and/or cooling device which is provided to set the temperature of the manipulator (in particular for cooling purposes). Further, the particle beam apparatus according to the system described herein includes, for example, a second heating and/or cooling device which is provided to set the temperature of the object (in particular for cooling purposes). By way of example, the manipulator and/or the object is/are cooled to a temperature of −140° C. or less than −140° C. using liquid nitrogen or using liquid helium. Hereinabove and also hereinbelow, temperatures below −50° C. are referred to as cryo-temperatures.

In a further embodiment of the particle beam apparatus according to the system described herein, the beam generator is embodied as a first beam generator and the particle beam is embodied as a first particle beam including first charged particles. Further, the objective lens is embodied as a first objective lens for focusing the first particle beam onto the object and/or onto the manipulator. Moreover, the particle beam apparatus according to the system described herein includes at least one second beam generator for generating a second particle beam including second charged particles. Further, the particle beam apparatus according to the system described herein includes at least one second objective lens for focusing the second particle beam onto the object and/or the manipulator.

In particular, provision is made for the particle beam apparatus to be embodied as an electron beam apparatus and/or as an ion beam apparatus.

### BRIEF DESCRIPTION OF DRAWINGS

Further practical embodiments and advantages of the system described herein are described below in conjunction with the drawings, in which:

FIG. 1 shows a first embodiment of a particle beam apparatus;

FIG. 2 shows a second embodiment of a particle beam apparatus;

FIG. 3 shows a third embodiment of a particle beam apparatus;

FIG. 4 shows a fourth embodiment of a particle beam apparatus;

FIG. 5 shows a fifth embodiment of a particle beam apparatus;

FIG. 6 shows a sixth embodiment of a particle beam apparatus;

FIG. 7 shows a schematic illustration of a manipulator;

FIG. 8 shows a schematic illustration of an object stage;

FIG. 9 shows a further schematic illustration of the object stage according to FIG. 8;

FIG. 10 shows a schematic illustration of a procedure of an embodiment of a method for fastening and moving an object;

FIG. 11 shows a schematic illustration of a particle beam apparatus, a manipulator, and an object;

FIG. 12 shows a further schematic illustration of a particle beam apparatus, a manipulator, and an object;

FIG. 13 shows an even further schematic illustration of a particle beam apparatus, a manipulator, and an object;

FIG. 14 shows yet a further schematic illustration of a particle beam apparatus, a manipulator, and an object;

FIG. 15 shows a schematic illustration of a procedure of a further embodiment of a method for fastening and moving an object; and

FIG. 16 shows a schematic illustration of a procedure of an even further embodiment of a method for fastening and moving an object.

### DETAILED DESCRIPTION OF VARIOUS EMBODIMENTS

The system described herein will now be explained in more detail using a particle beam apparatuses in the form of an SEM and in the form of a combination apparatus that includes an electron beam column and an ion beam column. Express reference is made to the fact that the system described herein can be used in any particle beam apparatus, in particular in any electron beam apparatus and/or any ion beam apparatus.

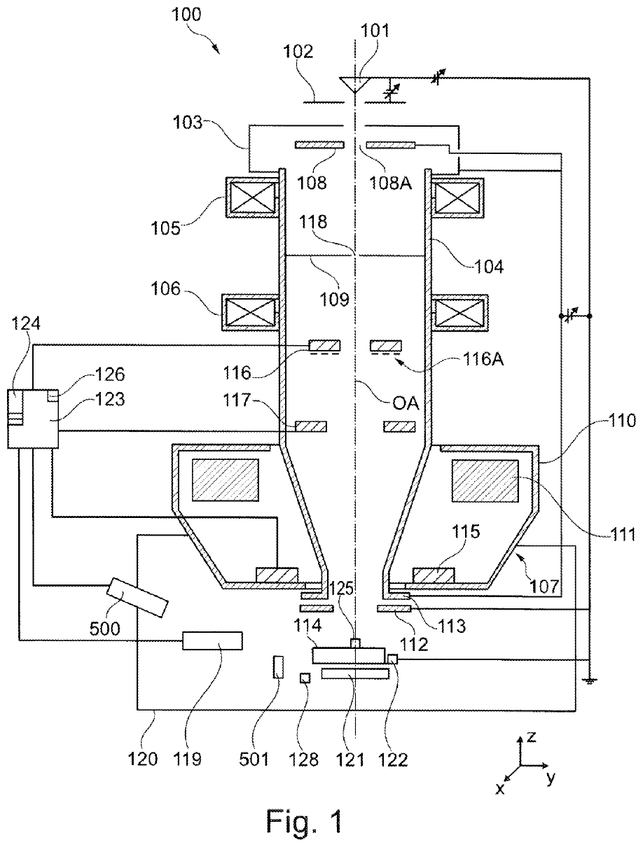

FIG. 1 shows a schematic illustration of an SEM 100. The SEM 100 includes a first beam generator in the form of an electron source 101, which is designed as a cathode. Further, the SEM 100 is provided with an extraction electrode 102 and with an anode 103, which is placed onto one end of a beam guiding tube 104 of the SEM 100. By way of example, the electron source 101 is embodied as a thermal field emitter. However, the invention is not restricted to such an electron source 101. Rather, any electron source is utilizable.

Electrons emerging from the electron source 101 form a primary electron beam. The electrons are accelerated to anode potential owing to a potential difference between the electron source 101 and the anode 103. In the embodiment depicted here, the anode potential is 100 V to 35 kV, for example 5 kV to 15 kV, in particular 8 kV, relative to a ground potential of a housing of a sample chamber 120. However, alternatively the anode potential could also be at ground potential.

Two condenser lenses, specifically a first condenser lens 105 and a second condenser lens 106, are arranged at the beam guiding tube 104. Here, proceeding from the electron source 101 as viewed in the direction of a first objective lens 107, the first condenser lens 105 is arranged first, followed by the second condenser lens 106. It is expressly pointed out that further embodiments of the SEM 100 may include only a single condenser lens. A first aperture unit 108 is arranged between the anode 103 and the first condenser lens 105. Together with the anode 103 and the beam guiding tube 104, the first aperture unit 108 is at a high-voltage potential, specifically the potential of the anode 103, or connected to ground. The first aperture unit 108 has numerous first apertures 108A, of which one is depicted in FIG. 1. By way of example, two first apertures 108A are present. Each one of the numerous first apertures 108A has a different aperture diameter. Using an adjustment mechanism (not depicted), it is possible to set a desired first aperture 108A onto an optical axis OA of the SEM 100. Reference is explicitly made to the fact that, in further embodiments, the first aperture unit 108 may be provided with only a single aperture 108A. In this embodiment, an adjustment mechanism may not be provided. The first aperture unit 108 is then configured to be stationary. A stationary second aperture unit 109 is arranged between the first condenser lens 105 and the second condenser lens 106. As an alternative thereto, provision is made for the second aperture unit 109 to be configured to be movable.

The first objective lens 107 includes pole pieces 110, in which a hole is formed. The beam guiding tube 104 is guided through the hole. A coil 111 is arranged in the pole pieces 110.

An electrostatic retardation device is arranged in a lower region of the beam guiding tube 104. The electrostatic retardation device includes an individual electrode 112 and a tube electrode 113. The tube electrode 113 is arranged at one end of the beam guiding tube 104, the one end facing an object 125 that is arranged at an object holder 114 configured to be movable.

Together with the beam guiding tube 104, the tube electrode 113 is at the potential of the anode 103, while the individual electrode 112 and the object 125 are at a lower potential in relation to the potential of the anode 103. In the present case, the potential of the anode 103 is the ground potential of the housing of the sample chamber 120. In this manner, the electrons of the primary electron beam can be decelerated to a desired energy which is required for examining the object 125.

The SEM 100 further includes a scanning device 115 that deflects and scans the primary electron beam over the object 125. Here, the electrons of the primary electron beam interact with the object 125. As a result of the interaction, interaction particles arise, which are detected. In particular, electrons are emitted from the surface of the object 125—so-called secondary electrons—or electrons of the primary electron beam are backscattered—so-called backscattered electrons—as interaction particles.

The object 125 and the individual electrode 112 can also be at different potentials and potentials different from ground. It is thereby possible to set the location of the retardation of the primary electron beam in relation to the object 125. By way of example, if the retardation is carried out quite close to the object 125, imaging aberrations become smaller.

A detector arrangement that includes a first detector 116 and a second detector 117 is arranged in the beam guiding tube 104 for detecting the secondary electrons and/or the backscattered electrons. Here, the first detector 116 is arranged on the source side along the optical axis OA, while the second detector 117 is arranged on the object side along the optical axis OA in the beam guiding tube 104. The first detector 116 and the second detector 117 are arranged offset from one another in the direction of the optical axis OA of the SEM 100. Both the first detector 116 and the second detector 117 have a respective passage opening, through which the primary electron beam can pass. The first detector 116 and the second detector 117 are approximately at the potential of the anode 103 and of the beam guiding tube 104. The optical axis OA of the SEM 100 runs through the respective passage openings.

The second detector 117 serves principally for detecting secondary electrons. Upon emerging from the object 125, the secondary electrons initially have a low kinetic energy and random directions of motion. Using the strong extraction field emanating from the tube electrode 113, the secondary electrons are accelerated in the direction of the first objective lens 107. The secondary electrons enter the first objective lens 107 approximately parallel. The beam diameter of the beam of the secondary electrons remains small in the first objective lens 107 as well. The first objective lens 107 then has a strong effect on the secondary electrons and generates a comparatively short focus of the secondary electrons with sufficiently steep angles with respect to the optical axis OA, such that the secondary electrons diverge far apart from one another downstream of the focus and strike the second detector 117 on the active area thereof. By contrast, only a small proportion of electrons that are backscattered at the object 125—that is to say backscattered electrons which have a relatively high kinetic energy in comparison with the secondary electrons upon emerging from the object 125—are detected by the second detector 117. The high kinetic energy and the angles of the backscattered electrons with respect to the optical axis OA upon emerging from the object 125 have the effect that a beam waist, which is to say a beam region having a minimum diameter, of the backscattered electrons lies in the vicinity of the second detector 117. A large portion of the backscattered electrons passes through the passage opening of the second detector 117. Therefore, the first detector 116 substantially serves to detect the backscattered electrons.

In a further embodiment of the SEM 100, the first detector 116 can additionally be designed with an opposing field grid 116A. The opposing field grid 116A is arranged on the side of the first detector 116 directed toward the object 125. With respect to the potential of the beam guiding tube 104, the opposing field grid 116A has a negative potential such that only backscattered electrons with a high energy pass through the opposing field grid 116A to the first detector 116. Additionally or as an alternative, the second detector 117 includes a further opposing field grid, which has an analogous embodiment to the aforementioned opposing field grid 116A of the first detector 116 and which has an analogous function.

The detection signals generated by the first detector 116 and the second detector 117 are used to generate an image or images of the surface of the object 125.

It is expressly pointed out that the apertures of the first aperture unit 108 and of the second aperture unit 109, as well as the passage openings of the first detector 116 and of the second detector 117, are depicted in exaggerated fashion. The passage openings of the first detector 116 and of the second detector 117 have an extent perpendicular to the optical axis OA in the range of 0.5 mm to 5 mm. By way of example, the passage openings are of circular design and have a diameter in the range of 1 mm to 3 mm perpendicular to the optical axis OA.

The second aperture unit 109 is configured as a pinhole aperture unit in the embodiment illustrated here and is provided with a second aperture 118 for the passage of the primary electron beam, which has an extent in the range from 5 μm to 500 μm, for example 35 μm. As an alternative thereto, provision is made in a further embodiment for the second aperture unit 109 to be provided with a plurality of apertures, which can be displaced mechanically with respect to the primary electron beam or which can be reached by the primary electron beam by the use of electrical and/or magnetic deflection elements. The second aperture unit 109 is configured as a pressure stage aperture unit. This separates a first region, in which the electron source 101 is arranged and in which there is an ultra-high vacuum (10⁻⁷ hPa to 10⁻¹² hPa), from a second region, which has a high vacuum (10⁻³ hPa to 10⁻⁷ hPa). The second region is the intermediate pressure region of the beam guiding tube 104, which leads to the sample chamber 120.

The sample chamber 120 is under vacuum. For the purposes of producing the vacuum, a pump (not depicted) is arranged at the sample chamber 120. In the embodiment depicted in FIG. 1, the sample chamber 120 is operated in a first pressure range or in a second pressure range. The first pressure range includes only pressures of less than or equal to 10⁻³ hPa, and the second pressure range includes only pressures of greater than 10⁻³ hPa. To ensure the pressure ranges, the sample chamber 120 is vacuum-sealed.

The object holder 114 is arranged at an object stage 122. The object stage 122 is configured to be movable in three directions arranged perpendicular to one another, specifically in an x-direction (first stage axis), in a y-direction (second stage axis) and in a z-direction (third stage axis). Moreover, the object stage 122 can be rotated about two rotation axes which are arranged perpendicular to one another (stage rotation axes). The invention is not restricted to the object stage 122 described above. Rather, the object stage 122 can have further translation axes and rotation axes along which or about which the object stage 122 can move.

The SEM 100 further includes a third detector 121, which is arranged in the sample chamber 120. More precisely, the third detector 121 is arranged downstream of the object stage 122, as viewed from the electron source 101 along the optical axis OA. The object stage 122, and hence the object holder 114, can be rotated in such a way that the primary electron beam can radiate through the object 125 arranged at the object holder 114. When the primary electron beam passes through the object 125 to be examined, the electrons of the primary electron beam interact with the material of the object 125 to be examined. The electrons passing through the object 125 to be examined are detected by the third detector 121.

Arranged in the sample chamber 120 is a radiation detector 119, which is used to detect interaction radiation, for example x-ray radiation and/or cathodoluminescent light. The radiation detector 119, the first detector 116, and the second detector 117, are connected to a control unit 123, which includes a monitor 124 and a processor 127. The third detector 121 is also connected to the control unit 123. This is not depicted for reasons of clarity. Additionally or alternatively, a further detector in the form of a chamber detector 500, in particular for detecting secondary electrons, may be arranged in the sample chamber 120. The chamber detector 500 is likewise connected to the control unit 123. The control unit 123 processes detection signals that are generated by the first detector 116, the second detector 117, the third detector 121, the radiation detector 119, and/or the chamber detector 500 and displays the detection signals in the form of images on the monitor 124.

The control unit 123 furthermore has a database 126, in which data are stored and from which data are read out.

Arranged on the object holder 114 is a first heating and/or cooling device 128, which is used to cool and/or heat the object holder 114 and consequently the object 125 arranged there. By way of example, the object holder 114 is cooled to a temperature of −140° C. or less than −140° C. using liquid nitrogen or liquid helium. A temperature measuring unit (not illustrated) is arranged in the sample chamber 120 for the purpose of determining a temperature of the object 125. By way of example, the temperature measuring unit is embodied as an infrared measuring apparatus or as a semiconductor temperature sensor. However, the invention is not restricted to the use of such temperature measuring units. Rather, any temperature measuring unit which is suitable for the invention can be used as temperature measuring unit.

The SEM 100 also includes a mobile manipulator 501, which is only depicted schematically in FIG. 1. The manipulator 501 is configured to hold and/or move the object 125 or a part of the object 125.

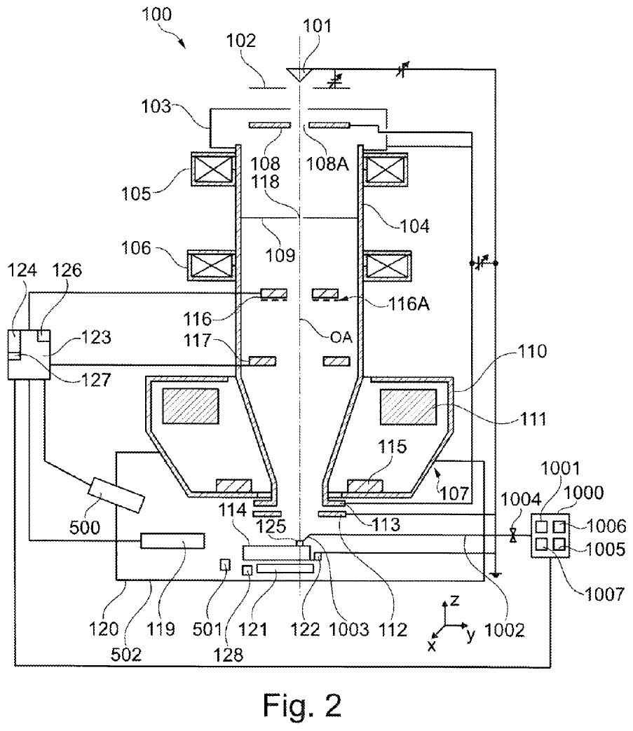

FIG. 2 shows a schematic illustration of a further SEM 100. The embodiment in FIG. 2 is based on the embodiment in FIG. 1. Identical components are provided with identical reference signs. In contrast to the embodiment of the SEM 100 according to FIG. 1, the SEM 100 according to FIG. 2 includes a gas feed device 1000. The gas feed device 1000 serves to feed a gaseous precursor to a specific position on the surface of the object 125 or of a unit of the SEM 100 explained further below. The gas feed device 1000 includes a precursor reservoir 1001. By way of example, the precursor is stored as a solid or liquid substance in the precursor reservoir 1001. To bring the precursor into the gaseous state, the precursor is evaporated or sublimated within the precursor reservoir 1001. By way of example, evaporating or sublimating the precursor can be influenced by controlling the temperature of the precursor reservoir 1001 and/or the precursor. As an alternative thereto, the precursor is stored in the precursor reservoir 1001 as a gaseous substance. By way of example, a precursor that includes metal is used as precursor to deposit a metal or a metal-containing layer on the surface of the object 125. By way of example, a non-conductive material, in particular SiO₂, may also be deposited onto the surface of the object 125. Furthermore, provision is also made for the precursor to be used for removing material of the object 125 upon interaction with a particle beam.

The gas feed device 1000 is provided with a feed line 1002. The feed line 1002 has, in the direction of the object 125, an acicular and/or capillary device, for example in the form of a hollow tube 1003, which in particular is able to be brought into the vicinity of the surface of the object 125, for example to a distance of 10 μm to 1 mm from the surface of the object 125. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 125. When the valve 1004 is closed, the flow of the gaseous precursor onto the surface of the object 125 is stopped.

The gas feed device 1000 is furthermore provided with an adjusting unit 1005, which enables an adjustment of the position of the hollow tube 1003 in all 3 spatial directions—namely an x-direction, a y-direction, and a z-direction—and an adjustment of the orientation of the hollow tube 1003 using a rotation and/or a tilt. The gas feed device 1000 and thus also the adjusting unit 1005 are connected to the control unit 123 of the SEM 100.

In further embodiments, the precursor reservoir 1001 is not arranged directly at the gas feed device 1000. Rather, in further embodiments, provision is made for the precursor reservoir 1001 to be arranged for example at a wall of a room in which the SEM 100 is situated. As an alternative thereto, provision is made for the precursor reservoir 1001 to be arranged in a first room and for the SEM 100 to be arranged in a second room separated from the first room. In yet a further alternative, provision is made for the precursor reservoir 1001 to be arranged in a cabinet device.

The gas feed device 1000 includes a temperature measuring unit 1006. By way of example, a resistance measuring device, a thermocouple, and/or a semiconductor temperature sensor is used as temperature measuring unit 1006. However, the invention is not restricted to the use of such temperature measuring units. Rather, any suitable temperature measuring unit which is suitable for the invention can be used as temperature measuring unit. In particular, provision can be made for the temperature measuring unit not to be disposed at the gas feed device 1000 itself, but rather to be disposed for example at a distance from the gas feed device 1000.

The gas feed device 1000 also includes a temperature setting unit 1007. By way of example, the temperature setting unit 1007 is a heating device, in particular a conventional infrared heating device, a heating wire, and/or a Peltier element. As an alternative thereto, the temperature setting unit 1007 is embodied as a heating and/or cooling device, which includes a heating wire, for example. However, the invention is not restricted to the use of such a temperature setting unit 1007. Rather, any suitable temperature setting unit can be used for the invention.

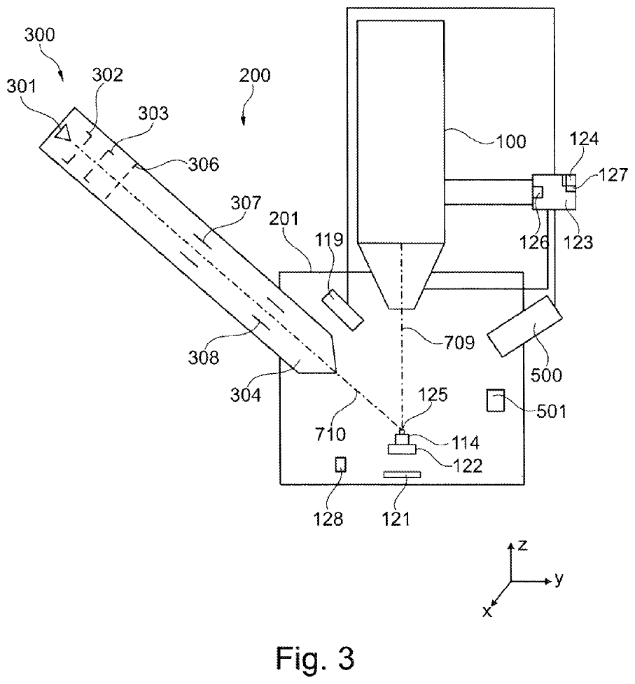

FIG. 3 shows a particle beam apparatus in the form of a combination apparatus 200. The combination apparatus 200 includes two particle beam columns. Firstly, the combination apparatus 200 is provided with the SEM 100, as already depicted in FIG. 1, but without the sample chamber 120. Rather, the SEM 100 is arranged at a sample chamber 201. The sample chamber 201 is under vacuum. For the purposes of producing the vacuum, a pump (not depicted) is arranged at the sample chamber 201. In the embodiment depicted in FIG. 3, the sample chamber 201 is operated in a first pressure range or in a second pressure range. The first pressure range includes only pressures of less than or equal to 10⁻³ hPa, and the second pressure range includes only pressures of greater than 10⁻³ hPa. To ensure the pressure ranges, the sample chamber 201 is vacuum-sealed.

The third detector 121 is arranged in the sample chamber 201.

The SEM 100 serves to generate a first particle beam, specifically the primary electron beam described further above, and has the optical axis, mentioned above, which is provided with the reference sign 709 in FIG. 3 and which is also referred to as first beam axis below. Secondly, the combination apparatus 200 is provided with an ion beam apparatus 300, which is likewise arranged at the sample chamber 201. The ion beam apparatus 300 likewise has an optical axis, which is provided with the reference sign 710 in FIG. 3 and which is also referred to as second beam axis below.

The SEM 100 is arranged vertically in relation to the sample chamber 201. By contrast, the ion beam apparatus 300 is arranged in a manner inclined by an angle of approx. 0° to 90° in relation to the SEM 100. An arrangement of approx. 50° is depicted by way of example in FIG. 3. The ion beam apparatus 300 includes a second beam generator in the form of an ion beam generator 301. Ions, which form a second particle beam in the form of an ion beam, are generated by the ion beam generator 301. The ions are accelerated using an extraction electrode 302, which is at a predefinable potential. The second particle beam then passes through an ion optical unit of the ion beam apparatus 300, where the ion optical unit includes a condenser lens 303 and a second objective lens 304. The second objective lens 304 ultimately generates an ion probe, which is focused onto the object 125 arranged at an object holder 114. The object holder 114 is arranged at an object stage 122.

An adjustable or selectable aperture unit 306, a first electrode arrangement 307, and a second electrode arrangement 308 are arranged above the second objective lens 304 (i.e., in the direction of the ion beam generator 301), with the first electrode arrangement 307 and the second electrode arrangement 308 being embodied as scanning electrodes. The second particle beam is scanned over the surface of the object 125 using the first electrode arrangement 307 and the second electrode arrangement 308, with the first electrode arrangement 307 acting in a first direction and the second electrode arrangement 308 acting in a second direction, which is counter to the first direction. Hence, scanning is carried out in a first direction, for example. The scanning in a second direction perpendicular thereto is brought about by further electrodes (not depicted), which are rotated by 90°, at the first electrode arrangement 307 and at the second electrode arrangement 308.

As explained above, the object holder 114 is arranged on the object stage 122. In the embodiment shown in FIG. 3, too, the object stage 122 is embodied to be movable in three directions arranged perpendicular to one another, specifically in an x-direction (first stage axis), in a y-direction (second stage axis) and in a z-direction (third stage axis).

Moreover, the object stage 122 can be rotated about two rotation axes which are arranged perpendicular to one another (stage rotation axes).

The distances depicted in FIG. 3 between the individual units of the combination apparatus 200 are depicted in exaggerated fashion in order to better illustrate the individual units of the combination apparatus 200.

Arranged in the sample chamber 201 is a radiation detector 119, which is used to detect interaction radiation, for example x-ray radiation and/or cathodoluminescent light. The radiation detector 119 is connected to a control unit 123, which includes a monitor 124 and a processor 127. Additionally or alternatively, a further detector in the form of a chamber detector 500, in particular for detecting secondary electrons, may be arranged in the sample chamber 201. It is likewise connected to the control unit 123.

The control unit 123 processes detection signals that are generated by the first detector 116, the second detector 117 (not depicted in FIG. 3), the third detector 121, the radiation detector 119, and/or the chamber detector 500 and displays the detection signals in the form of images on the monitor 124.

The control unit 123 furthermore has a database 126, in which data are stored and from which data are read out.

Arranged on the object holder 114 is a first heating and/or cooling device 128, which is used to cool and/or heat the object holder 114 and consequently the object 125 arranged there. By way of example, the object holder 114 is cooled to a temperature of −140° C. or less than −140° C. using liquid nitrogen or liquid helium. A temperature measuring unit (not illustrated) is arranged in the sample chamber 201 for the purpose of determining a temperature of the object 125. By way of example, the temperature measuring unit is embodied as an infrared measuring apparatus or as a semiconductor temperature sensor. However, the invention is not restricted to the use of such temperature measuring units. Rather, any temperature measuring unit which is suitable for the invention can be used as temperature measuring unit.

The combination apparatus 200 also includes a mobile manipulator 501, which is only depicted schematically in FIG. 3. The manipulator 501 is configured to hold and/or move the object 125 or a part of the object 125.

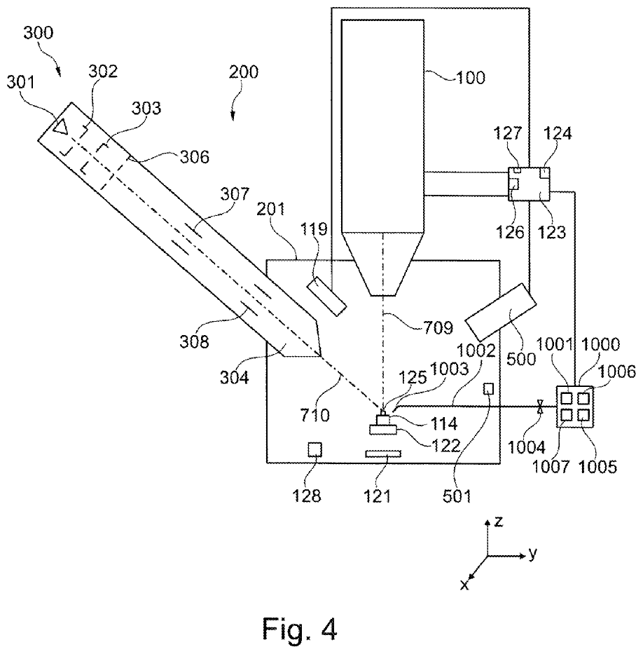

FIG. 4 shows a schematic illustration of a further combination apparatus 200. The embodiment in FIG. 4 is based on the embodiment in FIG. 3. Identical components are provided with identical reference signs. In contrast to the embodiment of the combination apparatus 200 according to FIG. 3, the combination apparatus 200 according to FIG. 4 includes a gas feed device 1000. The gas feed device 1000 serves to feed a gaseous precursor to a specific position on the surface of the object 125 or of a unit of the combination apparatus 200 explained further below. The gas feed device 1000 includes a precursor reservoir 1001. By way of example, the precursor is stored as a solid or liquid substance in the precursor reservoir 1001. To bring the precursor into the gaseous state, the precursor is evaporated or sublimated within the precursor reservoir 1001. By way of example, this procedure can be influenced by controlling the temperature of the precursor reservoir 1001 and/or the precursor. As an alternative thereto, the precursor is stored in the precursor reservoir 1001 as a gaseous substance. By way of example, a precursor including metal is used as precursor to deposit a metal or a metal-containing layer on the surface of the object 125. By way of example, a non-conductive material, in particular SiO₂, may also be deposited onto the surface of the object 125. Furthermore, provision is also made for the precursor to be used for removing material of the object 125 upon interaction with the particle beam.

The gas feed device 1000 is provided with a feed line 1002. The feed line 1002 has, in the direction of the object 125, an acicular and/or capillary device, for example in the form of a hollow tube 1003, which in particular is able to be brought into the vicinity of the surface of the object 125, for example to a distance of 10 μm to 1 mm from the surface of the object 125. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 125. When the valve 1004 is closed, the flow of the gaseous precursor onto the surface of the object 125 is stopped.

The gas feed device 1000 is furthermore provided with an adjusting unit 1005, which enables an adjustment of the position of the hollow tube 1003 in all 3 spatial directions—namely an x-direction, a y-direction, and a z-direction—and an adjustment of the orientation of the hollow tube 1003 using a rotation and/or a tilt. The gas feed device 1000 and thus also the adjusting unit 1005 are connected to the control unit 123 of the SEM 100.

In further embodiments, the precursor reservoir 1001 is not arranged directly at the gas feed device 1000. Rather, in the further embodiments, provision is made for the precursor reservoir 1001 to be arranged for example at a wall of a room in which the combination apparatus 200 is situated. As an alternative thereto, provision is made for the precursor reservoir 1001 to be arranged in a first room and for the combination apparatus 200 to be arranged in a second room separated from the first room. In yet a further alternative, provision is made for the precursor reservoir to be arranged in a cabinet device.

The gas feed device 1000 includes a temperature measuring unit 1006. By way of example, a resistance measuring device, a thermocouple, and/or a semiconductor temperature sensor is used as temperature measuring unit 1006. However, the invention is not restricted to the use of such temperature measuring units. Rather, any temperature measuring unit which is suitable for the invention can be used as temperature measuring unit. In particular, provision can be made for the temperature measuring unit not to be disposed at the gas feed device 1000 itself, but rather to be disposed for example at a distance from the gas feed device 1000.

The gas feed device 1000 further includes a temperature setting unit 1007. By way of example, the temperature setting unit 1007 is a heating device, in particular a conventional infrared heating device, a heating wire, and/or a Peltier element. As an alternative thereto, the temperature setting unit 1007 is embodied as a heating and/or cooling device, which includes a heating wire, for example. However, the invention is not restricted to the use of such a temperature setting unit 1007. Rather, any suitable temperature setting unit can be used for the invention.

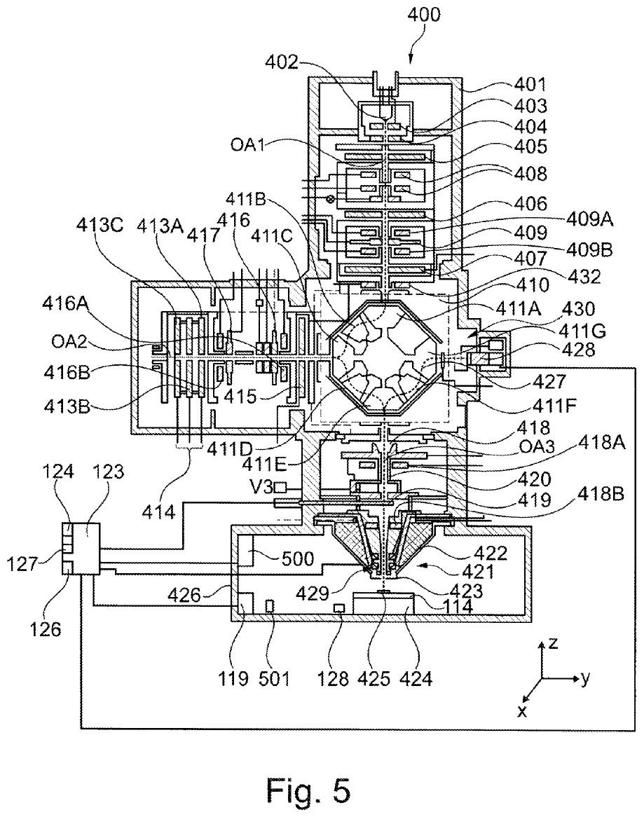

FIG. 5 is a schematic illustration of a further embodiment of a particle beam apparatus according to the system described herein. This embodiment of the particle beam apparatus is provided with the reference sign 400 and includes a mirror corrector for correcting chromatic and/or spherical aberrations, for example. The particle beam apparatus 400 includes a particle beam column 401, which is embodied as an electron beam column and which substantially corresponds to an electron beam column of a corrected SEM. However, the particle beam apparatus 400 is not restricted to an SEM with a mirror corrector. Rather, the particle beam apparatus can include any type of corrector units.

The particle beam column 401 includes a particle beam generator in the form of an electron source 402 (cathode), an extraction electrode 403, and an anode 404. By way of example, the electron source 402 is designed as a thermal field emitter. Electrons emerging from the electron source 402 are accelerated to the anode 404 owing to a potential difference between the electron source 402 and the anode 404. Accordingly, a particle beam in the form of an electron beam is formed along a first optical axis OA1.

The particle beam is guided along a beam path, which corresponds to the first optical axis OA1, after the particle beam has emerged from the electron source 402. A first electrostatic lens 405, a second electrostatic lens 406, and a third electrostatic lens 407 are used to guide the particle beam.

Furthermore, the particle beam is set along the beam path using a beam guiding device. The beam guiding device of this embodiment includes a source setting unit with two magnetic deflection units 408 arranged along the first optical axis OA1. Moreover, the particle beam apparatus 400 includes electrostatic beam deflection units. A first electrostatic beam deflection unit 409, which is also embodied as a quadrupole in a further embodiment, is arranged between the second electrostatic lens 406 and the third electrostatic lens 407. The first electrostatic beam deflection unit 409 is likewise arranged downstream of the magnetic deflection units 408. A first multi-pole unit 409A in the form of a first magnetic deflection unit is arranged at one side of the first electrostatic beam deflection unit 409. Moreover, a second multi-pole unit 409B in the form of a second magnetic deflection unit is arranged at the other side of the first electrostatic beam deflection unit 409. The first electrostatic beam deflection unit 409, the first multi-pole unit 409A, and the second multi-pole unit 409B are set for the purposes of setting the particle beam with respect to the axis of the third electrostatic lens 407 and the entrance window of a beam deflection device 410. The first electrostatic beam deflection unit 409, the first multi-pole unit 409A, and the second multi-pole unit 409B can interact like a Wien filter. A further magnetic deflection element 432 is arranged at the entrance to the beam deflection device 410.

The beam deflection device 410 is used as a particle beam deflector, which deflects the particle beam in a specific manner. The beam deflection device 410 includes a plurality of magnetic sectors, specifically a first magnetic sector 411A, a second magnetic sector 411B, a third magnetic sector 411C, a fourth magnetic sector 411D, a fifth magnetic sector 411E, a sixth magnetic sector 411F, and a seventh magnetic sector 411G. The particle beam enters the beam deflection device 410 along the first optical axis OA1 and the particle beam is deflected by the beam deflection device 410 in the direction of a second optical axis OA2. The beam deflection is performed using the first magnetic sector 411A, using the second magnetic sector 411B, and using the third magnetic sector 411C through an angle of 30° to 120°. The second optical axis OA2 is oriented at the same angle with respect to the first optical axis OA1. The beam deflection device 410 also deflects the particle beam which is guided along the second optical axis OA2, to be precise in the direction of a third optical axis OA3. The beam deflection is provided by the third magnetic sector 411C, the fourth magnetic sector 411D, and the fifth magnetic sector 411E. In the embodiment in FIG. 5, the deflection with respect to the second optical axis OA2 and with respect to the third optical axis OA3 is provided by deflection of the particle beam at an angle of 90°. Hence, the third optical axis OA3 runs coaxially with respect to the first optical axis OA1. However, it is pointed out that the particle beam apparatus 400 according to the invention is not restricted to deflection angles of 90°. Rather, any suitable deflection angle can be selected by the beam deflection device 410, for example 70° or 110°, such that the first optical axis OA1 does not run coaxially with respect to the third optical axis OA3. Further details of the beam deflection device 410 are provided by WO 2002/067286 A2.

After the particle beam has been deflected by the first magnetic sector 411A, the second magnetic sector 411B, and the third magnetic sector 411C, the particle beam is guided along the second optical axis OA2. The particle beam is guided to an electrostatic mirror 414 and travels on its path to the electrostatic mirror 414 along a fourth electrostatic lens 415, a third multi-pole unit 416A in the form of a magnetic deflection unit, a second electrostatic beam deflection unit 416, a third electrostatic beam deflection unit 417, and a fourth multi-pole unit 416B in the form of a magnetic deflection unit. The electrostatic mirror 414 includes a first mirror electrode 413A, a second mirror electrode 413B, and a third mirror electrode 413C. Electrons of the particle beam which are reflected back at the electrostatic mirror 414 once again travel along the second optical axis OA2 and re-enter the beam deflection device 410. Then, the electrons of the particle beam which are reflected back are deflected to the third optical axis OA3 by the third magnetic sector 411C, the fourth magnetic sector 411D, and the fifth magnetic sector 411E.

The electrons of the particle beam emerge from the beam deflection device 410 and are guided along the third optical axis OA3 to an object 425 that is intended to be examined and is arranged in an object holder 114. On the path to the object 425, the particle beam is guided to a fifth electrostatic lens 418, a beam guiding tube 420, a fifth multi-pole unit 418A, a sixth multi-pole unit 418B, and an objective lens 421. The fifth electrostatic lens 418 is an electrostatic immersion lens. By way of the fifth electrostatic lens 418, the particle beam is decelerated or accelerated to an electric potential of the beam guiding tube 420.

Using the objective lens 421, the particle beam is focused into a focal plane in which the object 425 is arranged. The object holder 114 is arranged at a mobile object stage 424. The movable object stage 424 is arranged in a sample chamber 426 of the particle beam apparatus 400. The object stage 424 is embodied to be movable in three directions arranged perpendicular to one another, specifically in an x-direction (first stage axis), in a y-direction (second stage axis), and in a z-direction (third stage axis). Moreover, the object stage 424 can be rotated about two rotation axes which are arranged perpendicular to one another (stage rotation axes).

The sample chamber 426 is under vacuum. For the purposes of producing the vacuum, a pump (not depicted) is arranged at the sample chamber 426. In the embodiment depicted in FIG. 5, the sample chamber 426 is operated in a first pressure range or in a second pressure range. The first pressure range includes only pressures of less than or equal to 10⁻³ hPa, and the second pressure range includes only pressures of greater than 10⁻³ hPa. To ensure the pressure ranges, the sample chamber 426 is vacuum-sealed.

The objective lens 421 can be configured as a combination of a magnetic lens 422 and a sixth electrostatic lens 423. The end of the beam guiding tube 420 can furthermore be an electrode of an electrostatic lens. After emerging from the beam guiding tube 420, particles of the particle beam are decelerated to a potential of the object 425. The objective lens 421 is not restricted to a combination of the magnetic lens 422 and the sixth electrostatic lens 423. Rather, the objective lens 421 can assume any suitable form. By way of example, the objective lens 421 can also be configured as a purely magnetic lens or as a purely electrostatic lens.

The particle beam which is focused onto the object 425 interacts with the object 425. Interaction particles are generated. In particular, secondary electrons are emitted from the object 425 or backscattered electrons are backscattered at the object 425. The secondary electrons or the backscattered electrons are accelerated again and guided into the beam guiding tube 420 along the third optical axis OA3. In particular, the trajectories of the secondary electrons and the backscattered electrons extend on the route of the beam path of the particle beam in the opposite direction to the particle beam.

The particle beam apparatus 400 includes a first analysis detector 419, which is arranged between the beam deflection device 410 and the objective lens 421 along the beam path. Secondary electrons travelling in directions oriented at a large angle with respect to the third optical axis OA3 are detected by the first analysis detector 419. Backscattered electrons and secondary electrons which have a small axial distance with respect to the third optical axis OA3 at the location of the first analysis detector 419—i.e., backscattered electrons and secondary electrons which have a small distance from the third optical axis OA3 at the location of the first analysis detector 419—enter the beam deflection device 410 and are deflected to a second analysis detector 428 by the fifth magnetic sector 411E, the sixth magnetic sector 411F, and the seventh magnetic sector 411G along a detection beam path 427. By way of example, the deflection angle is 90° or 110°.

The first analysis detector 419 generates detection signals which are largely generated by emitted secondary electrons. The detection signals which are generated by the first analysis detector 419 are guided to a control unit 123 and are used to obtain information about the properties of the interaction region of the focused particle beam with the object 425. In particular, the focused particle beam is scanned over the object 425 using a scanning device 429. Using the detection signals generated by the first analysis detector 419, an image of the scanned region of the object 425 can then be generated and displayed on a display unit. The display unit is, for example, a monitor 124 that is arranged at the control unit 123. The control unit 123 additionally includes a processor 127.

The second analysis detector 428 is also connected to the control unit 123. Detection signals of the second analysis detector 428 are passed to the control unit 123 and used to generate an image of the scanned region of the object 425 and to display the image on a display unit. The display unit is for example the monitor 124 that is arranged at the control unit 123.

Arranged at the sample chamber 426 is a radiation detector 119, which is used to detect interaction radiation, for example x-ray radiation and/or cathodoluminescent light. The radiation detector 119 is connected to the control unit 123, which includes the monitor 124. The control unit 123 processes detection signals of the radiation detector 119 and displays the detection signals in the form of images on the monitor 124.

The control unit 123 furthermore has a database 126, in which data are stored and from which data are read out.

Moreover, the particle beam apparatus 400 includes a chamber detector 500 which is connected to the control unit 123.

Arranged on the object holder 114 is a first heating and/or cooling device 128, which is used to cool and/or heat the object holder 114 and consequently the object 425 arranged on the object holder 114. By way of example, the object holder 114 is cooled to a temperature of −140° C. or less than −140° C. using liquid nitrogen or liquid helium. A temperature measuring unit (not illustrated) is arranged in the sample chamber 426 for the purpose of determining a temperature of the object 425. By way of example, the temperature measuring unit is embodied as an infrared measuring apparatus or as a semiconductor temperature sensor. However, the invention is not restricted to the use of such temperature measuring units. Rather, any temperature measuring unit which is suitable for the invention can be used as temperature measuring unit.

The particle beam apparatus 400 also includes a mobile manipulator 501, which is only depicted schematically in FIG. 5. The manipulator 501 is configured to hold and/or move the object 425 or a part of the object 425.

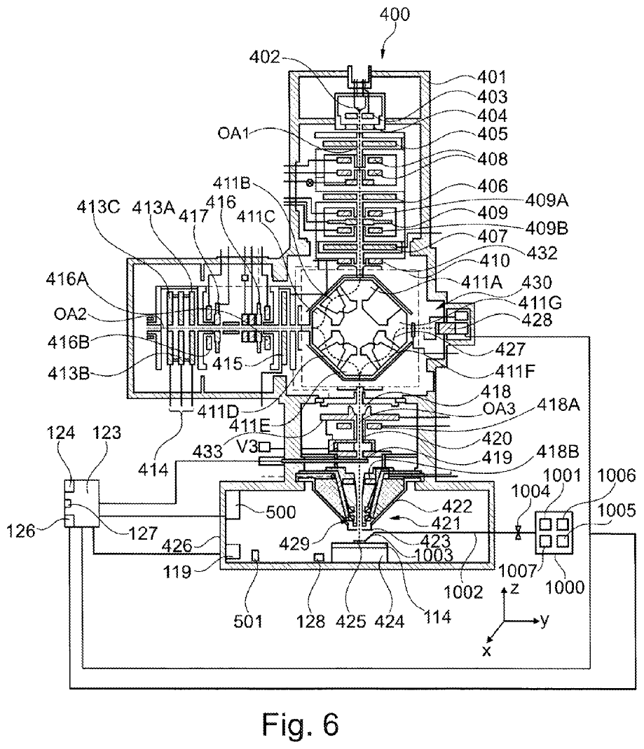

FIG. 6 shows a schematic illustration of a further particle beam apparatus 400. The embodiment in FIG. 6 is based on the embodiment in FIG. 5. Identical components are provided with identical reference signs. In contrast to the embodiment of the particle beam apparatus 400 according to FIG. 5, the combination apparatus according to FIG. 6 includes a gas feed device 1000. The gas feed device 1000 serves to feed a gaseous precursor to a specific position on the surface of the object 425 or of a unit of the particle beam apparatus 400 explained further below. The gas feed device 1000 includes a precursor reservoir 1001. By way of example, the precursor is stored as a solid or liquid substance in the precursor reservoir 1001. To bring the precursor into the gaseous state, the precursor is evaporated or sublimated within the precursor reservoir 1001. By way of example, this procedure can be influenced by controlling the temperature of the precursor reservoir 1001 and/or the precursor. As an alternative thereto, the precursor is stored in the precursor reservoir 1001 as a gaseous substance. By way of example, a precursor that includes metal will be used as precursor to deposit a metal or a metal-containing layer on the surface of the object 425. By way of example, a non-conductive material, in particular SiO₂, may also be deposited onto the surface of the object 425. Furthermore, provision is also made for the precursor to be used for removing material of the object 425 upon interaction with the particle beam.

The gas feed device 1000 is provided with a feed line 1002. The feed line 1002 has, in the direction of the object 425, an acicular and/or capillary device, for example in the form of a hollow tube 1003, which in particular is able to be brought into the vicinity of the surface of the object 425, for example to a distance of 10 μm to 1 mm from the surface of the object 425. The hollow tube 1003 has a feed opening, the diameter of which is for example in the range of 10 μm to 1000 μm, in particular in the range of 100 μm to 600 μm. The feed line 1002 has a valve 1004 in order to regulate the flow rate of gaseous precursor into the feed line 1002. Expressed differently, when the valve 1004 is opened, gaseous precursor from the precursor reservoir 1001 is introduced into the feed line 1002 and guided via the hollow tube 1003 to the surface of the object 425. When the valve 1004 is closed, the flow of the gaseous precursor onto the surface of the object 425 is stopped.

The gas feed device 1000 is furthermore provided with an adjusting unit 1005, which enables an adjustment of the position of the hollow tube 1003 in all 3 spatial directions—namely an x-direction, a y-direction, and a z-direction—and an adjustment of the orientation of the hollow tube 1003 using a rotation and/or a tilt. The gas feed device 1000 and thus also the adjusting unit 1005 are connected to the control unit 123 of the particle beam apparatus 400.

In further embodiments, the precursor reservoir 1001 is not arranged directly at the gas feed device 1000. Rather, in further embodiments, provision is made for the precursor reservoir 1001 to be arranged for example at a wall of a room in which the particle beam apparatus 400 is situated. As an alternative thereto, provision is made for the precursor reservoir 1001 to be arranged in a first room and for the particle beam apparatus 400 to be arranged in a second room separated from the first room. In yet a further alternative, provision is made for the precursor reservoir 1001 to be arranged in a cabinet device.

The gas feed device 1000 includes a temperature measuring unit 1006. By way of example, a resistance measuring device, a thermocouple, and/or a semiconductor temperature sensor is used as temperature measuring unit 1006. However, the invention is not restricted to the use of such temperature measuring units. Rather, any temperature measuring unit which is suitable for the invention can be used as temperature measuring unit. In particular, provision can be made for the temperature measuring unit not to be disposed at the gas feed device 1000 itself, but rather to be disposed for example at a distance from the gas feed device 1000.

The gas feed device 1000 further includes a temperature setting unit 1007. By way of example, the temperature setting unit 1007 is a heating device, in particular a conventional infrared heating device, a heating wire, and/or a Peltier element. As an alternative thereto, the temperature setting unit 1007 is embodied as a heating and/or cooling device, which includes a heating wire, for example. However, the invention is not restricted to the use of such a temperature setting unit 1007. Rather, any suitable temperature setting unit can be used for the invention.

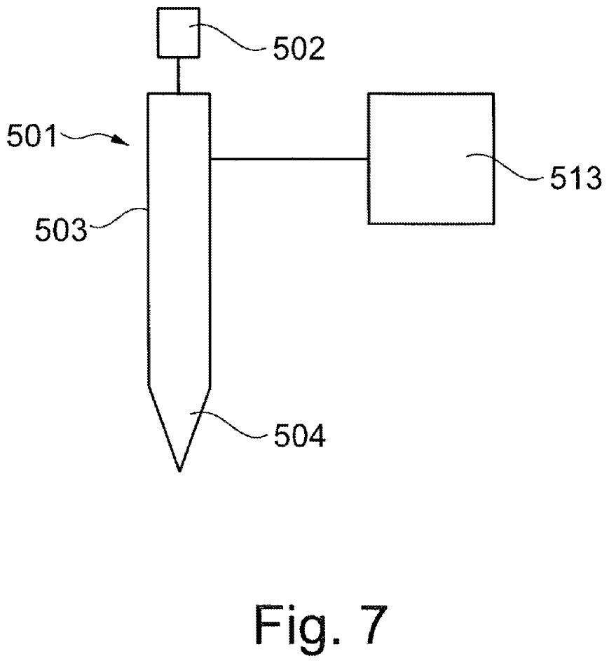

FIG. 7 shows a schematic illustration of an embodiment of the manipulator 501, which is used for example in the SEM 100 according to FIG. 1 or 2, in the combination apparatus 200 according to FIG. 3 or 4 and in the particle beam apparatus 400 according to FIG. 5 or 6. The manipulator 501 is configured to hold at least a part of the object 125, 425, to guide and/or to move part of the object 125, 425. The manipulator 501 has a main body 503. One end of the main body 503 has been provided with a tip 504. The manipulator 501 is arranged on a movement device 513. The movement device 513 renders available a movement of the manipulator 501. By way of the movement device 513, the manipulator 501 is movable in three directions arranged perpendicular to one another, namely in an x-direction, in a y-direction and in a z-direction. Moreover, the manipulator 501 can be rotated about two rotational axes which are arranged perpendicular to one another. The invention is not restricted to the above-described movements of the manipulator 501. Rather, the manipulator 501 can have further translation axes and rotational axes along which or about which the manipulator 501 can move.

Arranged on the manipulator 501 is a second heating and/or cooling device 502, which is used to cool and/or heat the manipulator 501. A temperature measuring unit (not illustrated) is arranged in the sample chamber 120, 201, 426 for the purpose of determining a temperature of the object 125, 425 and/or the manipulator 501. By way of example, this temperature measuring unit is embodied as an infrared measuring apparatus or as a semiconductor temperature sensor. However, the invention is not restricted to the use of such temperature measuring units. Rather, any temperature measuring unit which is suitable for the invention can be used as temperature measuring unit.

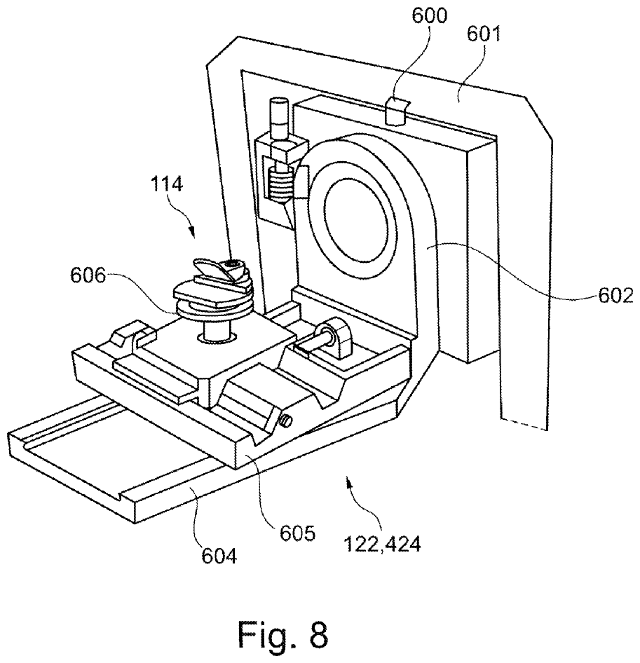

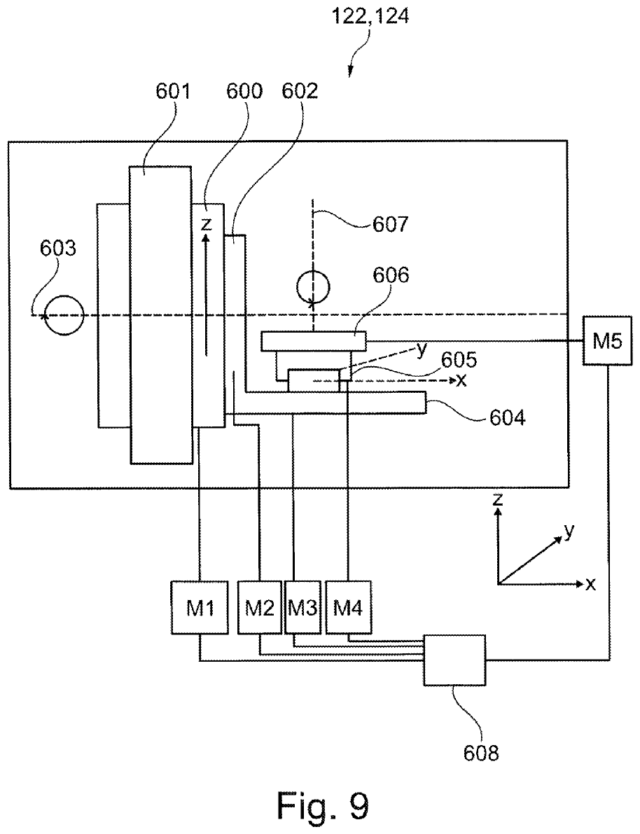

Now, the object stage 122, 424 of the particle beam apparatuses 100, 200 and 400 explained above is discussed in detail hereinbelow. The object stage 122, 424 is embodied as a movable object stage, which is illustrated schematically in FIGS. 8 and 9. Reference is made to the fact that the invention is not restricted to the object stage 122, 424 described here. Rather, the invention can include any movable object stage that is suitable for the invention.

The object holder 114 is arranged on the object stage 122, 424. The object stage 122, 424 has movement elements that ensure a movement of the object stage 122, 424 in such a way that a region of interest on the object can be examined using a particle beam and/or a light beam, for example. The movement elements are illustrated schematically in FIGS. 8 and 9 and are explained below.

The object stage 122, 424 has a first movement element 600, which is arranged, for example, at a housing 601 of the sample chamber 120, 201 or 426, in which the object stage 122, 424 is arranged in turn. The first movement element 600 enables a movement of the object stage 122, 424 along the z-axis (third stage axis). Further, provision is made of a second movement element 602. The second movement element 602 enables a rotation of the object stage 122, 424 about a first stage rotation axis 603, which is also referred to as a tilt axis. This second movement element 602 serves to tilt the object 125, 425 about the first stage rotation axis 603, where the object 125, 425 is arranged on the object holder 114.

Arranged at the second movement element 602, in turn, is a third movement element 604 that is embodied as a guide for a slide and that ensures that the object stage 122, 424 is movable in the x-direction (first stage axis). The aforementioned slide is a further movement element in turn, namely a fourth movement element 605. The fourth movement element 605 is embodied in such a way that the object stage 122, 424 is movable in the y-direction (second stage axis). To this end, the fourth movement element 605 has a guide in which a further slide is guided, the object holder 114 in turn being arranged at the further slide.

The object holder 114 is embodied, in turn, with a fifth movement element 606, which enables a rotation of the object holder 114 about a second stage rotation axis 607. The second stage rotation axis 607 is oriented perpendicular to the first stage rotation axis 603.

On account of the above-described arrangement, the object stage 122, 424 of the embodiment discussed here has the following kinematic chain: first movement element 600 (movement along the z-axis)—second movement element 602 (rotation about the first stage rotation axis 603)—third movement element 604 (movement along the x-axis) —fourth movement element 605 (movement along the y-axis)—fifth movement element 606 (rotation about the second stage rotation axis 607).

In a further embodiment (not illustrated), provision is made for further movement elements to be arranged at the object stage 122, 424 such that movements along further translational axes and/or about further rotation axes are made possible.

It is clear from FIG. 9 that each of the aforementioned movement elements is connected to a drive unit in the form of a motor M1 to M5. Thus, the first movement element 600 is connected to a first drive unit M1 and is driven on account of a driving force that is provided by the first drive unit M1. The second movement element 602 is connected to a second drive unit M2, which drives the second movement element 602. The third movement element 604 is connected, in turn, to a third drive unit M3. The third drive unit M3 provides a driving force for driving the third movement element 604. The fourth movement element 605 is connected to a fourth drive unit M4, where the fourth drive unit M4 drives the fourth movement element 605. Furthermore, the fifth movement element 606 is connected to a fifth drive unit M5. The fifth drive unit M5 provides a driving force that drives the fifth movement element 606.

The aforementioned drive units M1 to M5 can be embodied as stepper motors, for example, and are controlled by a drive control unit 608 and are each supplied with a supply current by the drive control unit 608 (cf. FIG. 9). It is explicitly pointed out that the invention is not restricted to the movement using stepper motors. Rather, any drive units can be used as drive units, for example brushless motors.

The control unit 123 of the SEM 100 according to FIG. 1 or 2, of the combination apparatus 200 according to FIG. 3 or 4, and/or of the particle beam apparatus 400 according to FIG. 5 or 6 includes the processor 127. Loaded into the processor 127 is a computer program product having a program code which, upon execution, carries out a method for operating the SEM 100 according to FIG. 1 or 2, the combination apparatus 200 according to FIG. 3 or 4, and/or the particle beam apparatus 400 according to FIG. 5 or 6. Embodiments of the method according to the system described herein are explained hereinbelow in relation to the combination apparatus 200 according to FIG. 3 or 4. Corresponding statements apply with regard to the SEM 100 according to FIG. 1 or 2 and the particle beam apparatus 400 according to FIG. 5 or 6.

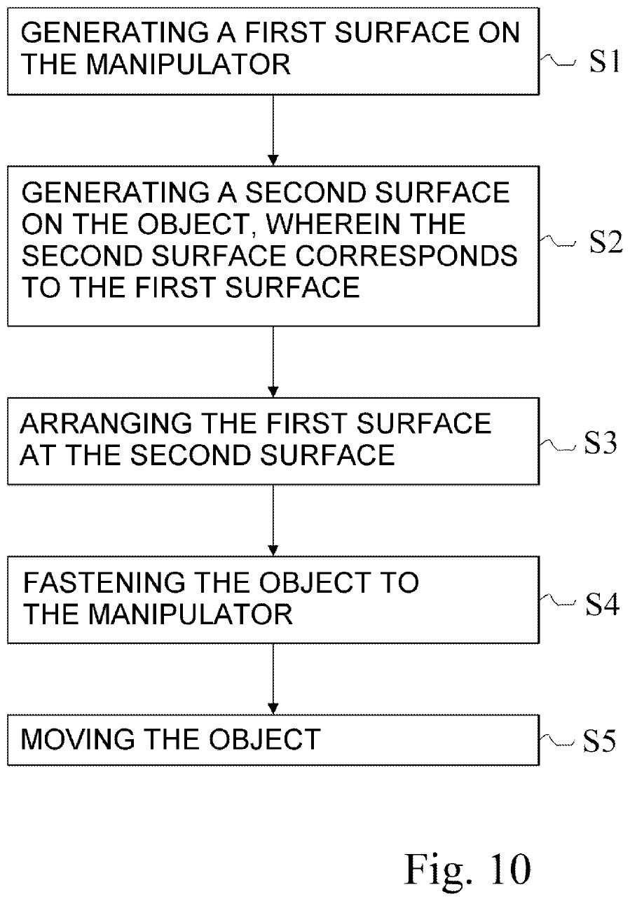

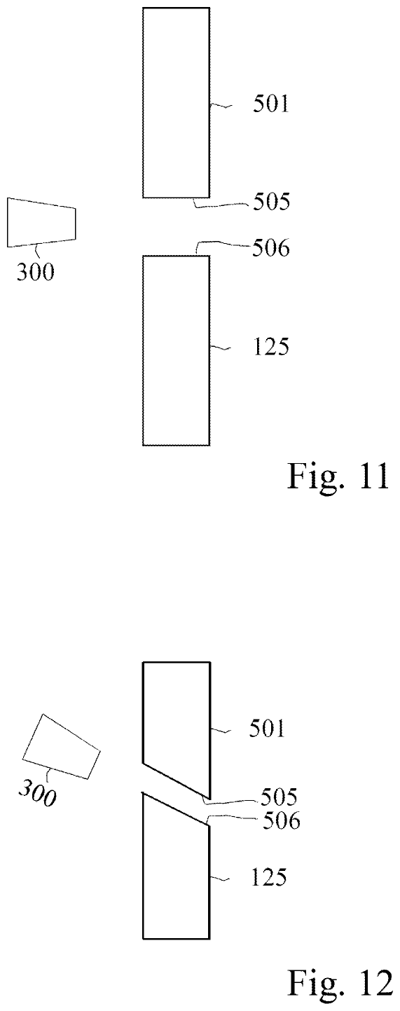

FIG. 10 shows an embodiment of the method according to the system described herein. In a method step S1, a first surface is generated on the manipulator 501 using the ion beam of the combination apparatus 200. FIG. 11 shows a schematic illustration of the ion beam apparatus 300, the manipulator 501, and the object 125. The first surface is provided with the reference sign 505. To generate the first surface 505 on the manipulator 501, the ion beam is guided onto the manipulator 501 and over the manipulator 501 using the first electrode arrangement 307 and the second electrode arrangement 308. In particular, provision is made for the first surface 505 on the manipulator 501 to be generated by ablating material from the manipulator 501 and/or by applying material to the manipulator 501. By way of example, the gas feed device 1000 including the precursor reservoir 1001 is used to this end to guide a precursor to the manipulator 501 using the hollow tube 1003. As a result of the interaction of the precursor with the ion beam, the first surface 505 is subsequently generated by ablating material from the manipulator 501 and/or by applying material to the manipulator 501.

In a method step S2, a second surface is generated on the object 125 using the ion beam of the combination apparatus 200. In FIG. 11, the second surface is provided with the reference sign 506. To generate the second surface 506 on the object 125, the ion beam is guided onto the object 125 and over the object 125 using the first electrode arrangement 307 and the second electrode arrangement 308. In particular, provision is made for the second surface 506 on the manipulator 501 to be generated by ablating material from the object 125 and/or by applying material to the object 125. By way of example, the gas feed device 1000 including the precursor reservoir 1001 is used to this end to guide a precursor to the object 125 using the hollow tube 1003. As a result of the interaction of the precursor with the ion beam, the second surface 506 is subsequently generated by ablating material from the object 125 and/or by applying material to the object 125.

The first surface 505 and the second surface 506 are generated in such a way that the second surface corresponds to the first surface. Expressed in other words, the first surface 505 and the second surface 506 are configured so that the first surface 505 and the second surface 506 correspond to one another. By way of example, the correspondence between the first surface 505 and the second surface 506 is up to 50%, up to 60%, up to 70%, up to 80%, up to 90%, or up to 100%.

In method step S3, the first surface 505 is arranged at the second surface 506 such that the manipulator 501 is arranged at the object 125. In particular, the first surface 505 is arranged at the second surface 506 by moving the manipulator 501 and/or by moving the object 125. In particular, the object 125 is moved by the mobile object stage 122, on which the object 125 is arranged via the object holder 114.

In method step S4, the object 125 is fastened to the manipulator 501 in a boundary region between the first surface 505 and the second surface 506 using the ion beam. The ion beam is guided onto the object 125 and over the object 125 using the first electrode arrangement 307 and the second electrode arrangement 308. In the process, material of the object 125 is ablated and reapplied in the boundary region between the first surface 505 and the second surface 506, with the result that the object 125 is fastened to the manipulator 501. In addition or as an alternative thereto, provision is made for the ion beam to be guided onto the manipulator 501 and over the manipulator 501. By way of example, the ion beam is guided onto the manipulator 501 and over the manipulator 501 using the first electrode arrangement 307 and the second electrode arrangement 308. In the process, material of the manipulator 501 is ablated and reapplied in the boundary region between the first surface 505 and the second surface 506, with the result that the object 125 is fastened to the manipulator 501.

In method step S5, the object 125 fastened to the manipulator 501 is moved using the manipulator 501 and/or the mobile object stage 122.

In the method, the first surface 505 is generated with a first shape and the second surface 506 is generated with a second shape. Expressed in other words, the first surface 505 is generated in such a way that it has the first shape. Further, the second surface 506 is generated in such a way that it has the second shape. Following the arrangement of the first surface 505 on the second surface 506, the first shape rests against the second shape. In particular, provision is made for the first surface 505 to be generated as a plane surface and/or for the second surface 506 to be generated as a plane surface. By way of example, the first surface 505 and the second surface 506 are generated in such a way that the first surface 505 and the second surface 506 are alignable parallel to one another (cf. FIG. 11). Expressed in other words, the first surface 505 and the second surface 506 are generated so that the first surface 505 extends parallel to the second surface after being arranged at the second surface 506.

FIG. 12 shows a further schematic illustration of the ion beam apparatus 300, the manipulator 501, and the object 125. In contrast to the embodiment of FIG. 11, the ion beam apparatus 300 is arranged with a tilt in relation to the object 125 in the embodiment of FIG. 12, with the result that the first surface 505 and the second surface 506 are arranged obliquely with respect to a vertically extending axis of the object 125. In the embodiment according to FIG. 12, too, the first surface 505 is generated as a plane surface and/or the second surface 506 is generated as a plane surface. By way of example, the first surface 505 and the second surface 506 are generated in such a way that the first surface 505 and the second surface 506 are alignable parallel to one another (cf. FIG. 12). Expressed in other words, the first surface 505 and the second surface 506 are generated so that the first surface 505 extends parallel to the second surface 506 after being arranged at the second surface 506.

The invention is not restricted to the above-described embodiments of the first surface 505 and the second surface 506. Rather, the first surface 505 and/or the second surface 506 can have any shape that is suitable for the invention. By way of example, the first surface 505 and/or the second surface 506 can be rounded-off and/or have plane areas. All that is essential is that the first surface 505 corresponds to the second surface 506. By way of example, an embodiment of the invention provides for the first shape to engage in the second shape and/or for the second shape to engage in the first shape. Further embodiments of generating the first surface 505 and the second surface 506 are explained hereinbelow.

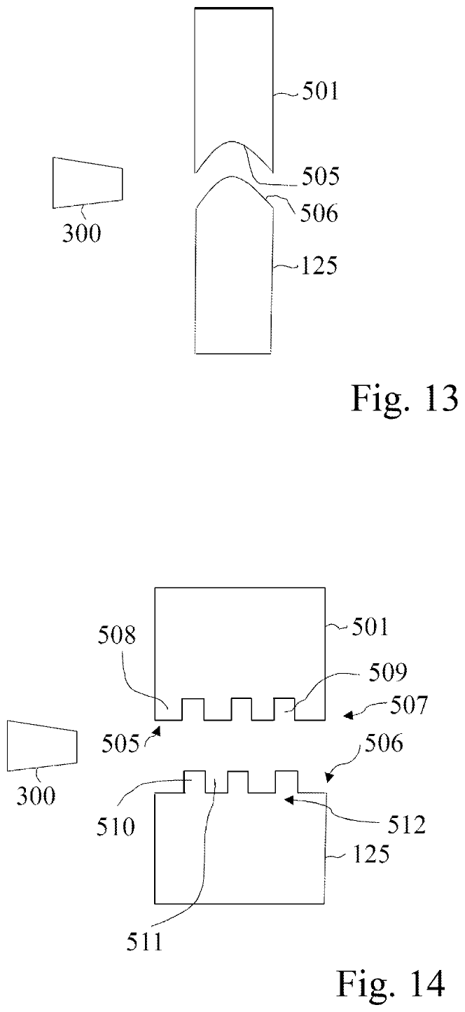

FIG. 13 shows a further schematic illustration of the ion beam apparatus 300, the manipulator 501, and the object 125. Following the first method step S1, the manipulator 501 has a first surface 505 which has a rounded-off form. Further, following method step S2, the object 125 has the second surface 506, which likewise has a rounded-off form. The rounding of the first surface 505 has a substantially concave form. By contrast, the rounding of the second surface 506 has a substantially convex form. In the embodiment described here, too, the first surface 505 and the second surface 506 are generated in such a way that the second surface 506 corresponds to the first surface 505.

In a further embodiment of the method according to the system described herein, method step S1 provides for a structure unit to be generated on the first surface 505 using the ion beam of the ion beam apparatus 300 when the first surface 505 is generated on the manipulator 501. When fastening the object 125 to the manipulator 501, the structure unit generated on the first surface 505 is arranged at the second surface 506.

In an even further embodiment of the method according to the system described herein, method step S1 provides for a structure unit to be generated on the first surface 505 using the ion beam of the ion beam apparatus 300 when the first surface 505 is generated on the manipulator 501. The structure unit includes at least one projection. When fastening the object 125 to the manipulator 501, the projection generated on the first surface 505 is arranged at the second surface 506.

In yet a further embodiment of the method according to the system described herein, method step S1 provides for a first structure unit to be generated on the first surface 505 using the ion beam of the ion beam apparatus 300 when the first surface 505 is generated on the manipulator 501. When fastening the object 125 to the manipulator 501, the first structure unit generated on the first surface 505 is arranged at a second structure unit of the second surface 506.

In an embodiment of the method according to the system described herein, method step S1 provides for a first structure unit to be generated on the first surface 505 using the ion beam of the ion beam apparatus 300 when the first surface 505 is generated on the manipulator 501. The first structure unit includes a first projection. When fastening the object 125 to the manipulator 501, the first projection of the first structure unit of the first surface 505 is arranged in a first cutout in a second structure unit of the second surface 506.

In a further embodiment of the method according to the system described herein, method step S1 provides for a first structure unit to be generated on the first surface 505 using the ion beam of the ion beam apparatus 300 when the first surface 505 is generated on the manipulator 501. Further, method step S2 provides for a second structure unit to be generated on the second surface 506 using the ion beam of the ion beam apparatus 300 when the second surface 506 is generated on the object 125. When fastening the object 125 to the manipulator 501, the first structure unit generated on the first surface 505 is arranged at the second structure unit of the second surface 506.

In an even further embodiment of the method according to the system described herein, method step S1 provides for a first structure unit to be generated on the first surface 505 using the ion beam of the ion beam apparatus 300 when the first surface 505 is generated on the manipulator 501. The first structure unit includes at least one first projection. Further, method step S2 provides for a second structure unit to be generated on the second surface 506 using the ion beam of the ion beam apparatus 300 when the second surface 506 is generated on the object 125. The second structure unit includes at least one first cutout. When fastening the object 125 to the manipulator 501, the first projection of the first structure unit is arranged in a second first cutout in the second structure unit.

The aforementioned structure units may have any design. By way of example, the aforementioned structure units have at least one aforementioned projection. In particular, provision is made for at least one of the aforementioned structure units to have a comb-like embodiment. Such a structure unit includes a plurality of tines (for example in the form of projections) and cutouts respectively arranged between two tines. This is illustrated in FIG. 14 in exemplary fashion. FIG. 14 shows yet a further schematic illustration of the ion beam apparatus 300, the manipulator 501, and the object 125. Following the first method step S1, the manipulator 501 has a first surface 505, on which a first structure unit 507 is formed. The first structure unit 507 has first projections 508 and first cutouts 509. Further, following method step S2, the object 125 has the second surface 506, on which a second structure unit 512 is arranged. The second structure unit 512 has second projections 510 and second cutouts 511. The first structure unit 507 and the second structure unit 512 are formed and generated so that the first structure unit 507 of the first surface 505 corresponds with the second structure unit 512 of the second surface 506. When fastening the object 125 to the manipulator 501, the first projections 508 of the first structure unit 507 engage in the second cutouts 511 in the second structure unit 512. Further, the second projections 510 of the second structure unit 512 engage in the first cutouts 509 in the first structure unit 507.

In yet a further embodiment of the method according to the system described herein, provision is additionally or alternatively made in method step S5 for the object 125 to be removed from an object material when the object 125 is moved using the manipulator 501 and/or the object stage 122. The object material remains on the object holder 114 of the object stage 122. The object material is the material out of which the object 125 intended to be analyzed, processed, and/or imaged was prepared.

In an embodiment of the method according to the system described herein, provision is additionally or alternatively made in method step S2 for the second surface 506 to be generated in such a way that the object 125 is embodied to be thicker at the second surface 506 than in other regions of the object 125. By way of example, this ensures that sufficient material is made available for redeposition and hence for good fastening of the object 125 to the manipulator 501.

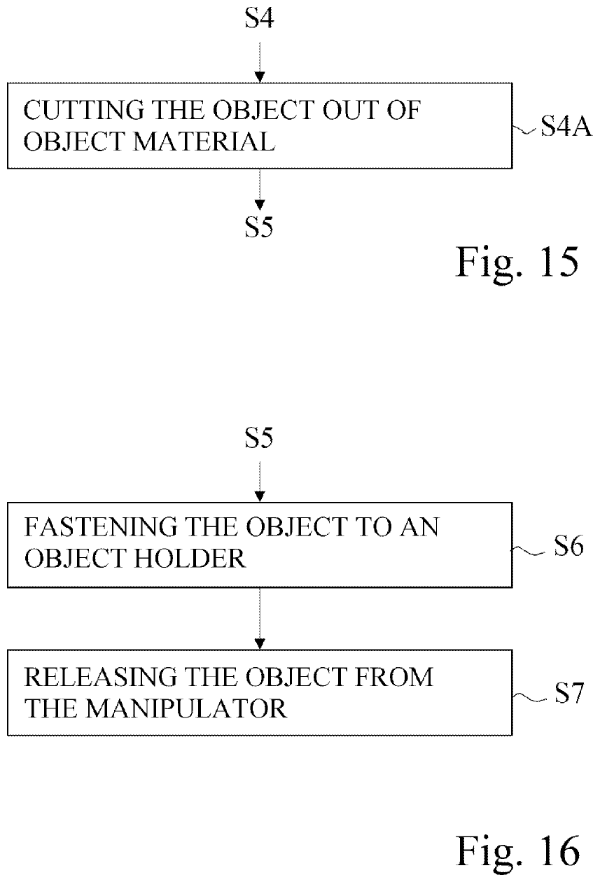

FIG. 15 shows an embodiment of the method according to the system described herein. The embodiment in FIG. 15 is based on the embodiment in FIG. 10. Therefore, reference is made to the explanations provided above, which also apply in this case. In contrast to the embodiment of the method according to FIG. 10, the embodiment of the method according to FIG. 15 provides for method step S4A to be carried out between method step S4 and method step S5. In method step S4A, the object 125 is cut out from an object material using the ion beam of the ion beam apparatus 300. The object material remains on the object holder 114 of the object stage 122. The object material is the material out of which the object 125 intended to be analyzed, processed, and/or imaged was prepared.

FIG. 16 shows an embodiment of the method according to the system described herein. The embodiment in FIG. 16 is based on the embodiment in FIG. 10. Therefore, reference is made to the explanations provided above, which also apply in this case. In contrast to the embodiment of the method according to FIG. 10, the embodiment of the method according to FIG. 16 provides for the object 125 to be fastened to an object holder using the ion beam of the ion beam apparatus 300 (method step S6). By way of example, the object holder is in the form of a TEM object holder. However, the invention is not restricted to such object holders. Rather, any object holder suitable for the invention may be used. By way of example, to fasten the object 125 to the object holder, provision is made for the ion beam of the ion beam apparatus 300 to be guided onto the object 125 and over the object 125. In the process, material of the object 125 is ablated and reapplied in the boundary region between the object 125 and the object holder, with the result that the object 125 is fastened to the object holder. In addition or as an alternative thereto, provision is made for the ion beam of the ion beam apparatus 300 to be guided onto the object holder and over the object holder. In the process, material of the object holder is ablated and reapplied in the boundary region between the object 125 and the object holder, with the result that the object 125 is fastened to the object holder. In addition or as an alternative thereto, a precursor may also be guided to the object 125 and/or to the object holder for the purpose of ablating and/or applying material. Reference is made to the explanations given hereinbefore, which also apply here.

If the object 125 is arranged on the object holder, then the object 125 is released from the manipulator 501 using the ion beam of the ion beam apparatus 300 in this embodiment of the method according to the system described herein (method step S7). To release the object 125 from the manipulator 501, provision is made for the ion beam to be guided onto the object 125 and over the object 125. In the process, material is ablated in the boundary region between the object 125 and the manipulator 501 such that the object 125 is released from the manipulator 501. In addition or as an alternative thereto, a precursor may also be guided to the object 125 and/or to the manipulator 501 for the purpose of ablating material. Reference is made to the explanations given hereinbefore, which also apply here.

In a further embodiment of the method according to FIG. 10, further first surfaces 505 are generated on the manipulator 501 and further second surfaces 506 are generated on the object 125.

Thus, in method step S1, a further first surface 505 is generated on the manipulator 501 using the ion beam of the combination apparatus 200. To generate the further first surface 505 on the manipulator 501, the ion beam is guided onto the manipulator 501 and over the manipulator 501 using the first electrode arrangement 307 and the second electrode arrangement 308. In particular, provision is made for the further first surface 505 on the manipulator 501 to be generated by ablating material from the manipulator 501 and/or by applying material to the manipulator 501. By way of example, the gas feed device 1000 is used to this end to guide a precursor to the manipulator 501 using the hollow tube 1003. As a result of the interaction of the precursor with the ion beam, the further first surface 505 is subsequently generated by ablating material from the manipulator 501 and/or by applying material to the manipulator 501.

In method step S2, a further second surface 506 is generated on the object 125 using the ion beam of the combination apparatus 200. To generate the further second surface 506 on the object 125, the ion beam is guided onto the object 125 and over the object 125 using the first electrode arrangement 307 and the second electrode arrangement 308. In particular, provision is made for the further second surface 506 on the manipulator 501 to be generated by ablating material from the object 125 and/or by applying material to the object 125. By way of example, the gas feed device 1000 is used to this end to guide a precursor to the object 125 using the hollow tube 1003. As a result of the interaction of the precursor with the ion beam, the further second surface 506 is subsequently generated by ablating material from the object 125 and/or by applying material to the object 125.

The further first surface 505 and the further second surface 506 are generated in such a way that the further second surface 506 corresponds to the further first surface 505. Expressed in other words, the further first surface 505 and the further second surface 506 are configured so that the further first surface 505 and the further second surface 506 correspond to one another. By way of example, the correspondence between the further first surface 505 and the further second surface 506 is up to 50%, up to 60%, up to 70%, up to 80%, up to 90%, or up to 100%.

In method step S3, the further first surface 505 is furthermore arranged at the further second surface 506 such that the manipulator 501 is arranged at the object 125. In particular, the further first surface 505 is arranged at the further second surface 506 by moving the manipulator 501 and/or by moving the object 125. In particular, the object 125 is moved by the mobile object stage 122, on which the object 125 is arranged via the object holder 114.

In method step S4, the object 125 is additionally fastened to the manipulator 501 in a boundary region between the further first surface 505 and the further second surface 506 using the ion beam. The ion beam is guided onto the object 125 and over the object 125 using the first electrode arrangement 307 and the second electrode arrangement 308. In the process, material of the object 125 is ablated and reapplied in the boundary region between the further first surface 505 and the further second surface 506, with the result that the object 125 is fastened to the manipulator 501. In addition or as an alternative thereto, provision is made for the ion beam to be guided onto the manipulator 501 and over the manipulator 501. By way of example, the ion beam is guided onto the manipulator 501 and over the manipulator 501 using the first electrode arrangement 307 and the second electrode arrangement 308. In the process, material of the manipulator 501 is ablated and reapplied in the boundary region between the further first surface 505 and the further second surface 506, with the result that the object 125 is fastened to the manipulator 501.

The above-described method according to the system described herein has numerous advantages. The generation of the first surface 505 and the second surface 506, which corresponds to the first surface 505, and the arrangement of the first surface 505 on the second surface 506 allow a particularly good connection and a particularly good hold of the object 125 on the manipulator 501 in the boundary region between the first surface 505 and the second surface 506. It was found that the method according to the system described herein is particularly well suited to the arrangement of frozen objects 125 on the manipulator 501, in particular on a cooled manipulator 501. Accordingly, a contamination of components, which might occur within the scope of a cold deposition as explained above, is avoided. As a result, the manipulator 501 can be used multiple times without the manipulator 501 having to be cleaned or even replaced.

The features of the invention disclosed in the present description, in the drawings and in the claims may be essential for the realization of the invention in the various embodiments thereof both individually and in arbitrary combinations. The invention is not restricted to the described embodiments. It can be varied within the scope of the claims and taking into account the knowledge of the relevant person skilled in the art.

1. A method for fastening an object to a mobile manipulator in a particle beam apparatus and for moving the object in the particle beam apparatus, comprising:
generating at least one first surface on the manipulator using a particle beam of the particle beam apparatus, wherein the particle beam includes charged particles;
generating at least one second surface on the object using the particle beam of the particle beam apparatus such that the second surface corresponds to the first surface;
arranging the first surface at the second surface such that the manipulator is arranged at the object;
fastening the object to the manipulator in a boundary region between the first surface and the second surface using the particle beam of the particle beam apparatus; and
moving the object fastened to the manipulator using the manipulator and/or a mobile object stage, on which the object is arranged.

2. The method as claimed in claim 1, wherein the first surface is generated with a first shape, and wherein the second surface is generated with a second shape such that, following the arrangement of the first surface on the second surface, the first shape rests against the second shape and/or the first shape engages in the second shape and/or the second shape engages in the first shape.

3. The method as claimed in claim 1, wherein the first surface is generated as a plane surface and/or the second surface is generated as a plane surface.

4. The method as claimed in claim 1, wherein the first surface and the second surface are generated to be aligned parallel to one another.

5. The method as claimed in claim 1, wherein
at least one further first surface is generated on the manipulator using the particle beam of the particle beam apparatus,
at least one further second surface is generated on the object using the particle beam of the particle beam apparatus such that the further second surface corresponds to the further first surface,
the further first surface is arranged at the further second surface such that the manipulator is arranged at the object; and wherein,
using the particle beam of the particle beam apparatus, the object is fastened to the manipulator in a boundary region between the further first surface and the further second surface.

6. The method as claimed in claim 1, further comprising one of the following:
the particle beam of the particle beam apparatus is used to generate a structure unit on the first surface before the object is fastened to the manipulator, and the structure unit generated on the first surface is arranged at the second surface when the object is fastened to the manipulator;
the particle beam of the particle beam apparatus is used to generate a structure unit, having at least one projection, on the first surface before the object is fastened to the manipulator, and the projection is arranged at the second surface when the object is fastened to the manipulator;
the particle beam of the particle beam apparatus is used to generate a first structure unit on the first surface before the object is fastened to the manipulator, and the first structure unit generated on the first surface is arranged at a second structure unit of the second surface of the object when the object is fastened to the manipulator;
the particle beam of the particle beam apparatus is used to generate a first structure unit, having at least one first projection, on the first surface before the object is fastened to the manipulator, and the first projection of the first structure unit is arranged in a first cutout in a second structure unit of the second surface of the object when the object is fastened to the manipulator;
the particle beam of the particle beam apparatus is used to generate a first structure unit on the first surface and the particle beam of the particle beam apparatus is used to generate a second structure unit on the second surface, before the object is fastened to the manipulator, and the first structure unit generated on the first surface is arranged at the second structure unit, which was generated on the second surface, when the object is fastened to the manipulator;
the particle beam of the particle beam apparatus is used to generate a first structure unit, having at least one first projection, on the first surface and the particle beam of the particle beam apparatus is used to generate a second structure unit, having at least one second cutout, on the second surface, before the object is fastened to the manipulator, and the first projection is arranged in the second cutout when the object is fastened to the manipulator.

7. The method as claimed in claim 1, further comprising one of the following:
to fasten the object to the manipulator, the particle beam of the particle beam apparatus is guided to the object in such a way that material of the object is applied in the boundary region between the first surface and the second surface;
to fasten the object to the manipulator, the particle beam of the particle beam apparatus is guided to the manipulator in such a way that material of the manipulator is applied in the boundary region between the first surface and the second surface.

8. The method as claimed in claim 1, wherein the object is removed from an object material when the object is moved using the manipulator and/or the object stage.

9. The method as claimed in claim 1, wherein the object is cut out of an object material using the particle beam of the particle beam apparatus before the object is moved.

10. The method as claimed in claim 1, further comprising at least one of the following:
the object is fastened to an object holder using the particle beam of the particle beam apparatus after the object has been moved using the manipulator and/or the object stage;
the object is released from the manipulator using the particle beam of the particle beam apparatus after the object has been moved using the manipulator and/or the object stage.

11. The method as claimed in claim 1, wherein the object is fastened to the manipulator using a gas which is provided by a gas feed device.

12. The method as claimed in claim 1, wherein the object is cooled using a first heating and/or cooling device and/or the manipulator is cooled using a second heating and/or cooling device.

13. The method as claimed in claim 1, wherein the object is thicker at the first surface than in other regions of the object.

14. A non-transitory computer readable medium containing a program code which is loadable into a processor and which, when executed, controls a particle beam apparatus to perform the following:
generating at least one first surface on the manipulator using a particle beam of the particle beam apparatus, wherein the particle beam includes charged particles;
generating at least one second surface on the object using the particle beam of the particle beam apparatus such that the second surface corresponds to the first surface;
arranging the first surface at the second surface such that the manipulator is arranged at the object;
fastening the object to the manipulator in a boundary region between the first surface and the second surface using the particle beam of the particle beam apparatus; and
moving the object fastened to the manipulator using the manipulator and/or a mobile object stage, on which the object is arranged.

15. A particle beam apparatus for processing, imaging and/or analyzing an object, comprising:
at least one mobile manipulator;
at least one beam generator for generating a particle beam with charged particles;
at least one objective lens for focusing the particle beam onto the object and/or onto the manipulator;
at least one scanning device for scanning the particle beam over the object and/or over the manipulator;
at least one detector unit for detecting interaction particles and/or interaction radiation resulting from an interaction of the particle beam with the object and/or from an interaction of the particle beam with the manipulator; and
at least one processor coupled to a non-transitory computer readable medium that contains a program code which is loadable into the processor and which, when executed, controls the particle beam apparatus to generate at least one first surface on the manipulator using the particle beam, generate at least one second surface on the object using the particle beam of the particle beam apparatus such that the second surface corresponds to the first surface, arrange the first surface at the second surface such that the manipulator is arranged at the object, fasten the object to the manipulator in a boundary region between the first surface and the second surface using the particle beam of the particle beam apparatus and move the object fastened to the manipulator using the manipulator and/or a mobile object stage, on which the object is arranged.

16. The particle beam apparatus as claimed in claim 15, wherein the particle beam apparatus includes a gas feed device for feeding a gas.

17. The particle beam apparatus as claimed in claim 15, wherein the particle beam apparatus includes a heating and/or cooling device for setting a temperature of the manipulator and/or the object.

18. The particle beam apparatus as claimed in claim 15, further comprising:
at least one additional beam generator for generating an additional particle beam with additional charged particles; and
at least one additional objective lens for focusing the additional particle beam onto the object and/or onto the manipulator.

19. The particle beam apparatus as claimed in claim 15, wherein the particle beam apparatus is an electron beam apparatus and/or an ion beam apparatus.

20. The non-transitory computer readable medium as claimed in claim 14, wherein, to fasten the object to the manipulator, the particle beam of the particle beam apparatus is guided to the object or to the manipulator to apply material to the boundary region between the first surface and the second surface.
